(19) United States
(12) Patent Application Publication
(10) Pub. No.: US 2024/0413613 A1
(43) Pub. Date: Dec. 12, 2024

(54) SEMICONDUCTOR LASER AND METHOD FOR PRODUCING SEMICONDUCTOR LASER

(71) Applicant: Mitsubishi Electric Corporation, Tokyo (JP)

(72) Inventors: Naoki NAKAMURA, Tokyo (JP); Hiroyuki KAWAHARA, Tokyo (JP); Keisuke MATSUMOTO, Tokyo (JP); Ryoko SUZUKI, Tokyo (JP); Satoshi TAIRA, Tokyo (JP)

(73) Assignee: Mitsubishi Electric Corporation, Tokyo (JP)

(21) Appl. No.: 18/697,834

(22) PCT Filed: Nov. 30, 2021
(86) PCT No.: PCT/JP2021/043737

§ 371 Date: Apr. 2, 2024

(51) Int. Cl. H01S 5/22

(52) U.S. Cl. CPC H01S 5/2206

(57) ABSTRACT

A semiconductor laser includes a ridge structure formed on an n-type semiconductor substrate, and a buried layer buried so as to cover both sides of the ridge structure opposed to each other in a direction perpendicular to an extending direction of the ridge structure. The ridge structure includes an n-type cladding layer, an active layer, and a p-type cladding layer formed sequentially from a side of the n-type semiconductor substrate. The buried layer includes a p-type semiconductor layer in contact with both side surfaces of the p-type cladding layer and the active layer in the ridge structure, and a semi-insulating layer, and the p-type semiconductor layer is not in contact with the n-type cladding layer of the ridge structure.

### TECHNICAL FIELD

The present application relates to a semiconductor laser and a method for producing a semiconductor laser.

### BACKGROUND ART

Patent document 1 discloses an optical semiconductor device provided with a mesa stripe structure s2 including an n-type InP cladding layer s3, an active layer s4, and a p-type InP cladding layer s5 that are sequentially stacked, and a buried layer s7 buried on both sides of the mesa stripe structure s2. The active layer s4 has a multi-quantum well structure including a well layer and a carbon-added barrier layer, and the buried layer s7 includes a p-type InP layer s10, an Fe-doped InP layer s11, and an n-type InP layer s12 that are sequentially stacked. The side surfaces of the n-type InP cladding layer s3 and the p-type InP cladding layer s5 in the mesa stripe structure s2 are covered with the p-type InP layer s10, and the side surfaces of the active layer s4 in the mesa stripe structure s2 are not in contact with the p-type InP layer s10 but is in contact with the Fe-doped InP layer s11. Note that the reference numerals used in the present specification are distinguished by adding “s” to the reference numerals used in Patent Document 1.

The optical semiconductor device in Patent Document 1 has a modulation-doped structure in which carbon is added in the barrier layer in the active layer s4. In order to prevent the modulation-doped structure from being collapsed due to diffusion of zinc (Zn) as a p-type dopant from the p-type InP layer s10 to the active layer s4, the side surfaces of the active layer s4 is not in contact with the p-type InP layer s10, but is in contact with the iron (Fe)-doped InP layer s11.

Generally, a structure is adopted in which the side surfaces of the active layer s4 are in contact with the p-type InP layer s10. This structure is disclosed in FIG. 8 of Patent Document 1. In the optical semiconductor device disclosed in FIG. 8 of Patent Document 1 (comparative example of optical semiconductor device), the p-type InP layer s10 is in contact with the side surfaces of the p-type InP cladding layer s5, and therefore, when a hole current is made to flow from the p-type InP cladding layer s5 to the active layer s4 and an electron current is made to flow from the n-type InP cladding layer s3 to the active layer s4 to generate laser light, some holes leak into the p-type InP layer s10 on the side surfaces before the holes are injected from the p-type InP cladding layer s5 into the active layer s4, thereby resulting in a problem in that a reactive current that does not pass the active layer s4 occurs.

### CITATION LIST

### Patent Document

Patent Document 1: Japanese Patent Application Laid-Open No. 2016-31970 (FIG. 1)

### SUMMARY OF INVENTION

### Problems to be Solved by Invention

The optical semiconductor device disclosed in Patent Document 1 employs a structure in which the p-type InP layer s10 is not in contact with the side surfaces of the active layer s4, thereby avoiding degradation of the characteristics of the optical semiconductor device due to an optical loss caused by the carrier absorption and the inter-valence-band absorption in the active layer s4 as a result of the collapse of the modulation-doped structure in the case where the side surfaces of the active layer s4 is in contact with the p-type InP layer s10.

On the other hand, the p-type InP layer s10 has a function of preventing the electron current injected into the active layer s4 from overflowing due to heat and leaking from the side surfaces of the active layer s4 to the outside, that is, a function of an energy barrier with respect to the electrons. Since the optical semiconductor device of Patent Document 1 has a structure in which the p-type InP layer s10 is not in contact with the side surfaces of the active layer s4, the energy barrier with respect to the electron current is insufficient, and an overflow of electrons occurs particularly during a high-temperature operation. Thus, there is a concern that the optical power characteristics and the high-speed operation characteristics may be deteriorated. In particular, in the case where zinc (Zn), which is a dopant of the p-type InP layer s10 around the Fe-doped InP layer s11, may diffuse into the Fe-doped InP layer s11 in contact with the side surfaces of the active layer s4, and when the Fe-doped InP layer s11 ceases to function as a high-resistance semiconductor layer or a semi-insulating semiconductor layer, the performance degradation becomes more pronounced.

A technique disclosed in the specification of the present application aims to achieve a semiconductor laser capable of reducing a reactive current that does not pass through an active layer and improving optical output characteristics and high-speed operation performance.

### Means for Solving Problems

A semiconductor laser according to an example disclosed in the specification of the present application is a semiconductor laser that includes a ridge structure formed on an n-type semiconductor substrate, and a buried layer buried so as to cover both sides of the ridge structure opposed to each other in a direction perpendicular to an extending direction of the ridge structure. The ridge structure includes an n-type cladding layer, an active layer, and a p-type cladding layer formed sequentially from a side of the n-type semiconductor substrate. The buried layer includes a p-type semiconductor layer in contact with both side surfaces of the p-type cladding layer and the active layer in the ridge structure, and a semi-insulating layer, and the p-type semiconductor layer is not in contact with the n-type cladding layer of the ridge structure.

### Effect of Invention

In the semiconductor laser of the example disclosed in the specification of the present application, the p-type semiconductor layer in contact with both side surfaces of the p-type cladding layer and the active layer in the ridge structure is not in contact with the n-type cladding layer of the ridge structure, and thus the reactive current that does not pass through the active layer can be reduced, so that the optical output characteristics and the high-speed operation performance can be improved.

### BRIEF DESCRIPTION OF DRAWINGS

FIG. 1 is a diagram showing a cross-sectional structure of a semiconductor laser according to Embodiment 1.

FIG. 2 is an enlarged view of an area around an active layer of FIG. 1.

FIG. 3 is a diagram showing the active layer of FIG. 1.

FIG. 4 is an enlarged view of an area around an active layer of a comparative example.

FIG. 5 is a diagram showing a cross-sectional structure of a semiconductor laser according to Embodiment 2.

FIG. 6 is an enlarged view of an area around an active layer of FIG. 5.

FIG. 7 is a diagram showing a cross-sectional structure of a semiconductor laser according to Embodiment 3.

FIG. 8 is a diagram showing a method for manufacturing the semiconductor laser of FIG. 7.

FIG. 9 is a diagram showing the method for manufacturing the semiconductor laser of FIG. 7.

FIG. 10 is a diagram showing the method for manufacturing the semiconductor laser of FIG. 7.

FIG. 11 is a diagram showing the method for manufacturing the semiconductor laser of FIG. 7.

FIG. 12 is a diagram showing the method for manufacturing the semiconductor laser of FIG. 7.

FIG. 13 is a diagram showing the method for manufacturing the semiconductor laser of FIG. 7.

FIG. 14 is a diagram showing a cross-sectional structure of a first semiconductor laser according to Embodiment 4.

FIG. 15 is a diagram showing a method for manufacturing the semiconductor laser of FIG. 14.

FIG. 16 is a diagram showing the method for manufacturing the semiconductor laser of FIG. 14.

FIG. 17 is a diagram showing the method for manufacturing the semiconductor laser of FIG. 14.

FIG. 18 is a diagram showing a cross-sectional structure of a second semiconductor laser according to Embodiment 4.

FIG. 19 is a diagram showing a cross-sectional structure of a third semiconductor laser according to Embodiment 4.

FIG. 20 is a diagram showing a cross-sectional structure of a semiconductor laser according to Embodiment 5.

FIG. 21 is an enlarged view of an area around an active layer of FIG. 20.

FIG. 22 is a diagram showing energy bands of an extending portion base layer and a p-type semiconductor layer in FIG. 21.

FIG. 23 is a diagram showing a cross-sectional structure of a semiconductor laser according to Embodiment 6.

FIG. 24 is an enlarged view of an area around an active layer of FIG. 23.

FIG. 25 is a diagram showing a method for manufacturing the semiconductor laser of FIG. 23.

FIG. 26 is a diagram showing the method for manufacturing the semiconductor laser of FIG. 23.

FIG. 27 is a diagram showing a cross-sectional structure of a semiconductor laser according to Embodiment 7.

FIG. 28 is an enlarged view of an area around an active layer of FIG. 27.

FIG. 29 is a diagram showing a method for manufacturing the semiconductor laser of FIG. 27.

FIG. 30 is a diagram showing the method for manufacturing the semiconductor laser of FIG. 27.

FIG. 31 is a diagram showing the method for manufacturing the semiconductor laser of FIG. 27.

FIG. 32 is a diagram showing the method for manufacturing the semiconductor laser of FIG. 27.

FIG. 33 is a diagram showing the method for manufacturing the semiconductor laser of FIG. 27.

FIG. 34 is a diagram showing the method for manufacturing the semiconductor laser of FIG. 27.

FIG. 35 is a diagram showing a method for manufacturing a semiconductor laser according to Embodiment 8.

FIG. 36 is a diagram showing a cross-sectional structure of a semiconductor laser according to Embodiment 9.

FIG. 37 is an enlarged view of an area around an active layer of FIG. 36.

FIG. 38 is a diagram showing a method for manufacturing the semiconductor laser of FIG. 36.

FIG. 39 is a diagram showing the method for manufacturing the semiconductor laser of FIG. 36.

FIG. 40 is a diagram showing the method for manufacturing the semiconductor laser of FIG. 36.

FIG. 41 is a diagram showing the method for manufacturing the semiconductor laser of FIG. 36.

FIG. 42 is a diagram showing a method for manufacturing a semiconductor laser according to Embodiment 10.

### MODE FOR CARRYING OUT INVENTION

### Embodiment 1

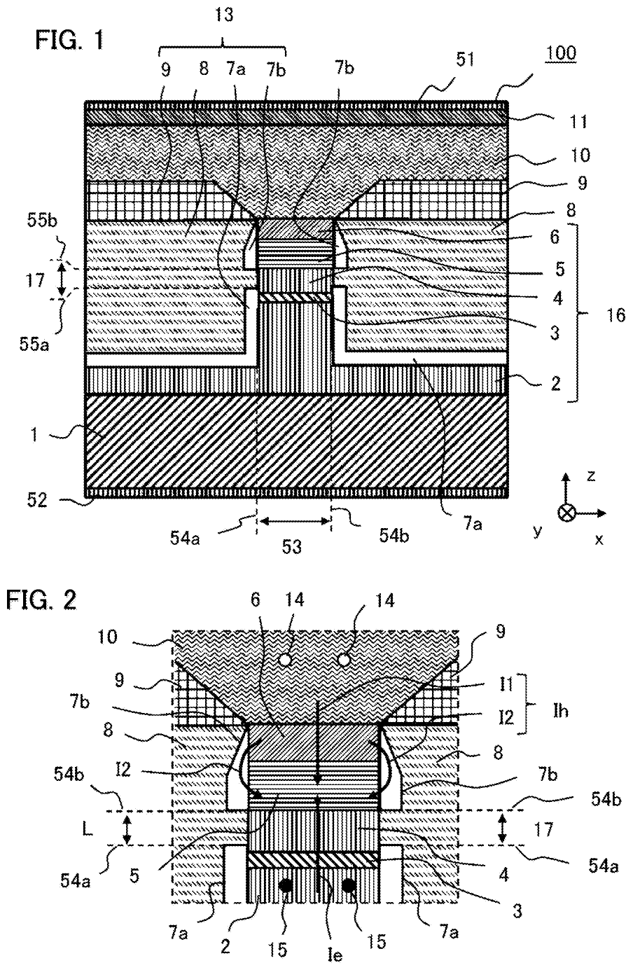

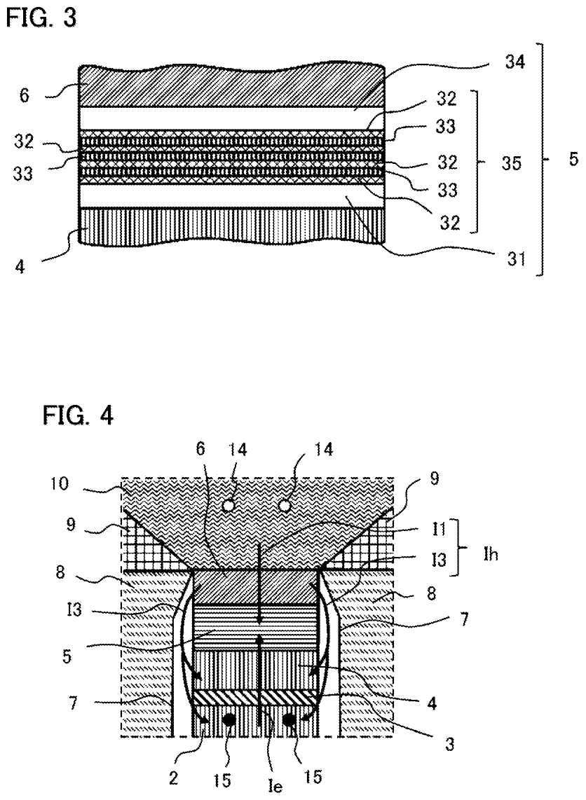

FIG. 1 is a diagram showing a cross-sectional structure of a semiconductor laser according to Embodiment 1, and FIG. 2 is an enlarged view of an area around an active layer of FIG. 1. FIG. 3 is a diagram showing the active layer of FIG. 1, and FIG. 4 is an enlarged view of an area around an active layer of a comparative example. The semiconductor laser 100 of Embodiment 1 is provided with: a first n-type cladding layer 2 of n-type InP formed on a surface of an n-type semiconductor substrate 1 that is an n-type InP substrate; a ridge structure 16 including a part of the first n-type cladding layer 2, a diffraction grating layer 3, a second n-type cladding layer 4 of n-type InP, an active layer 5, and a first p-type cladding layer 6 of p-type InP; p-type semiconductor layers 7a and 7b of p-type InP formed on both side surface of the ridge structure opposed to each other in a direction perpendicular to the extending direction of the ridge structure 16; a semi-insulating layer 8 covering both side surface of the part of the second n-type cladding layer 4 and the p-type semiconductor layers 7a and 7b; a block layer 9 of n-type InP formed on a surface of the semi-insulating layer 8; a second p-type cladding layer 10 of p-type InP formed on the surface of the block layer 9 and a surface of the first p-type cladding layer 6; a contact layer 11 of p-type InGaAs formed on a surface of the second p-type cladding layer 10; an anode electrode 51 formed on a surface of the contact layer 11; and a cathode electrode 52 formed on a rear surface opposite to the surface of the n-type semiconductor substrate 1. A semiconductor layer constituted with the p-type semiconductor layers 7a and 7b, the semi-insulating layer 8, and the block layer 9 is a buried layer 13 buried so as to cover both sides of the ridge structure opposed to each other in the direction perpendicular to the extending direction of the ridge structure 16. The semiconductor laser 100 shown in FIG. 1 is an example of a distributed feedback laser diode (DFB-LD). A direction perpendicular to the n-type semiconductor substrate 1 is defined as a z-direction, an extending direction of the ridge structure 16 perpendicular to the z-direction is defined as a y-direction, and a direction perpendicular to the z-direction and the y-direction is defined as an x-direction. The first n-type cladding layer 2, the diffraction grating layer 3, the second n-type cladding layer 4, the active layer 5, and the first p-type cladding layer 6, which constitute the ridge structure 16, are sequentially formed on the positive side in the z-direction. Both side surfaces of the ridge structure 16 in the x-direction and a side surface of the ridge structure 16 in the x-direction are referred to as both the side surfaces of the ridge structure 16 and the side surface of the ridge structure 16 as appropriate.

The p-type semiconductor layer 7a is formed on a surface of the first n-type cladding layer 2 on the positive side in the z-direction and on the side surfaces of the ridge structure 16 on the side of the n-type semiconductor substrate 1. The p-type semiconductor layer 7b is formed on the positive side in the z-direction on both the side surfaces of the ridge structure 16, the p-type semiconductor layer 7b being separated from the p-type semiconductor layer 7a with a separation portion 17 interposed therebetween. A region 53 of the ridge structure 16 in the x-direction is between a broken line 54a and a broken line 54b, and the separation portion 17 is between a broken line 55a and a broken line 55b. In the separation portion 17, the semi-insulating layer 8 is in contact with both side surfaces of the second n-type cladding layer 4, that is, both the side surfaces in the x-direction.

The material of the diffraction grating layer 3 is a material such as InGaAsP having a refractive index larger than that of InP. When the semiconductor laser 100 is not a DFB-LD, the diffraction grating layer 3 is not formed. The active layer 5 is typically constituted with a quantum well structure and a separate confinemente heterostructure (SCH). FIG. 3 shows the active layer 5 including a quantum well structure 35 in which a well layer 32 and a barrier layer 33 are alternately stacked, a light confinement layer 31 formed on the side of the second n-type cladding layer 4 of the quantum well structure 35, and a light confinement layer 34 formed on the side of the first p-type cladding layer 6. The quantum well structure 35 of the active layer 5 shown in FIG. 3 includes four well layers 32 and three barrier layers 33 formed between the well layers 32. The SCH structure is a structure including the optical confinement layers 31 and 34, which are layers for confining electrons and holes in the quantum well structure 35, as shown in FIG. 3. The well layer 32, the barrier layer 33, and the optical confinement layers 31 and 34 are made of, for example, AlGaInAs.

An end of the p-type semiconductor layer 7b on the side of the n-type semiconductor substrate 1 is preferably located below the interface initiating the quantum well structure 35 of the active layer 5, that is, the interface between the optical confinement layer 31 on the side of the second n-type cladding layer 4 and the well layer 32 formed thereon. When described using the separation portion 17, an end of the separation portion 17 on the side of the p-type semiconductor layer 7b is preferably located below the interface initiating the quantum well structure 35 of the active layer 5 on the side of the n-type semiconductor substrate 1; that is, the end is on the side of the n-type semiconductor substrate 1. A separation length L, which is the length of the separation portion 17 in the z-direction, may be a length sufficient to block a hole current. For example, the separation length L is about 0.2 μm.

A method for forming the ridge structure 16 will be described in a manufacturing method for manufacturing the semiconductor laser 100 according to Embodiment 3. The p-type semiconductor layers 7a and 7b separated by the separation portion 17 are formed, for example, as follows. In the case of the active layer 5 using a compound semiconductor containing aluminum (Al), the p-type semiconductor layers 7a and 7b do not grow on the side surfaces of the active layer 5 because an oxide layer is formed on the side surfaces of the active layer 5. Therefore, in the manufacturing process of the semiconductor laser of the comparative example shown in FIG. 4, hydrogen chloride (HCl) is added into the crystal growth furnace to remove the oxide layer on the side surfaces of the active layer 5, and then the p-type semiconductor layer 7 is grown. However, in Embodiment 1, the p-type semiconductor layers 7a and 7b are grown without removing the oxide layer with the hydrogen chloride addition. Thus, the p-type semiconductor layers 7a and 7b can be formed so as not to be in contact with the side surfaces of the active layer 5. After the p-type semiconductor layers 7a and 7b are formed on both the side surfaces of the ridge structure 16, an oxide layer is removed from the side surfaces of the active layer 5 by adding hydrogen chloride and then the semi-insulating layer 8 is grown, thereby forming the p-type semiconductor layers 7a and 7b and the semi-insulating layer 8 in the buried layer 13. The subsequent manufacturing steps are the same as those of Embodiment 3.

In order to generate laser light by operating the semiconductor laser 100, a hole current is injected into the semiconductor layers of semiconductor materials, that is, the contact layer 11, the second p-type cladding layer 10, and the first p-type cladding layer 6 and the active layer 5 in the ridge structure 16 via the anode electrode 51, and an electron current is injected into the semiconductor layers of the n-type semiconductor substrate 1 and the ridge structure 16, that is, the first n-type cladding layer 2, the diffraction grating layer 3, the second n-type cladding layer 4, and the active layer 5 via the cathode electrode 52. The semiconductor laser 100 of Embodiment 1 generates laser light by recombination of the holes 14 and the electrons 15 in the active layer 5.

The holes 14 as the majority carriers of the contact layer 11 and the second p-type cladding layer 10 move to the side of the active layer 5, and a hole current Ih flows. The hole current Ih is composed of a main current I1 flowing from the first p-type cladding layer 6 to the active layer 5 and a bypass current I2 flowing from the first p-type cladding layer 6 to the active layer 5 via the p-type semiconductor layer 7b. The bypass current I2 is a hole current component leaking from the first p-type cladding layer 6 into the p-type semiconductor layer 7b. However, the bypass current I2 cannot flow through the separation portion 17 where the semi-insulating layer 8 exists, and flows in the direction of the valence band of the active layer 5 that is at a lower energy level than the valence band of the p-type semiconductor layer 7b, so that the bypass current I2 is injected into the active layer 5.

Electrons 15, which are majority carriers of the n-type semiconductor substrate 1 and the first n-type cladding layer 2, move to the side of the active layer 5 and an electron current Ie flows. The electron current Ie flows through the diffraction grating layer 3 and the second n-type cladding layer 4 to the active layer 5. Since the side surfaces of the active layer 5, i.e., the side surfaces in the x-direction is in contact with the p-type semiconductor layer 7b and the energy level of the conduction band of the p-type semiconductor layer 7b is higher than that of the active layer 5, the p-type semiconductor layer 7b forms an energy barrier with respect to the electron current Ie, and the electron current Ie does not overflow in the direction from the active layer 5 toward the semi-insulating layer 8, i.e., in the x-direction. Therefore the semiconductor laser 100 of Embodiment 1 does not deteriorate in the characteristics of the semiconductor laser, that is, the optical output characteristics and the high-speed operation characteristics, particularly even in a high-temperature environment, unlike the optical semiconductor device of Patent Document 1.

In the separation portion 17, the second n-type cladding layer 4 and the semi-insulating layer 8 are in contact with each other. At this time, the electron current Ie does not overflow into the semi-insulating layer 8 due to the energy barrier formed by the junction between the two. Further, when the semi-insulating layer 8 is, for example, an iron (Fe)-doped semi-insulating layer so as to have a high resistance particularly to the electrons, the performance of suppressing the overflow of the electron current Ie from the second n-type cladding layer 4 to the semi-insulating layer 8 is further improved.

In the area around the active layer in the semiconductor laser of the comparative example shown in FIG. 4, the p-type semiconductor layer 7 is formed on the side surfaces of the ridge structure without the intervention of the separation portion 17. The hole current Ih for driving the semiconductor laser of the comparative example is composed of the main current I1 flowing from the first p-type cladding layer 6 to the active layer 5 and a bypass current I3 flowing from the first p-type cladding layer 6 to the second n-type cladding layer 4 and the first n-type cladding layer 2 via the p-type semiconductor layer 7. The electron current Ie for driving the semiconductor laser of the comparative example flows through the diffraction grating layer 3 and the second n-type cladding layer 4 to the active layer 5. In the semiconductor laser of the comparative example, as in the semiconductor laser 100 of Embodiment 1, the holes 14 and the electrons 15 recombine in the active layer 5 to generate laser light.

In the semiconductor laser of the comparative example, the bypass current I3, which is a part of the hole current Ih, leaks from the side surfaces of the first p-type cladding layer 6 in the x-direction to the p-type semiconductor layer 7. Since the bypass current I3 flows through the second n-type cladding layer 4 and the first n-type cladding layer 2 without flowing through the active layer 5, the bypass current I3 is a reactive current that does not pass through the active layer 5. Therefore, in the semiconductor laser of the comparative example, since the reactive current that does not pass through the active layer 5 is present, the characteristics of the semiconductor laser, that is, the optical output characteristics and the high-speed operation characteristics are deteriorated, and a high-output and high-speed semiconductor laser cannot be achieved, unlike the semiconductor laser 100 of Embodiment 1.

In the semiconductor laser 100 of Embodiment 1, the p-type semiconductor layer 7b arranged at a position farther from the n-type semiconductor substrate 1 than the separation portion 17 covers the side surfaces of the quantum well structure 35 in the x-direction in the active layer 5, so that the bypass current I2, which is a part of the hole current Ih and flows from the first p-type cladding layer 6 through the p-type semiconductor layer 7b, can be injected into the active layer 5, and the electron current Ie does not overflow from the active layer 5, unlike the semiconductor laser of the comparative example. Therefore, the semiconductor laser 100 of Embodiment 1 can prevent the reactive current that does not pass through the active layer 5, and can improve the optical output characteristics and the high-speed operation performance.

In the semiconductor laser of the comparative example, an area of a p-type layer connecting portion that is a portion where the side surface of the first p-type cladding layer 6 in the x-direction and the p-type semiconductor layer 7 are connected has variation in the manufacturing process. When the area of the p-type layer connecting portion varies, the amount of the hole current leaking to the p-type semiconductor layer 7, that is, the amount of the bypass current I3 varies, and thus the amount of the reactive current varies. Therefore, the semiconductor laser of the comparative example also has a large variation in laser characteristics.

Also in the semiconductor laser 100 of Embodiment 1, a p-type layer connecting portion that is a portion where the side surface of the first p-type cladding layer 6 in the x-direction and the p-type semiconductor layer 7b are connected is also present. The p-type layer connecting portion is affected by manufacturing variation, and the area of the p-type layer connecting portion varies. However, in the semiconductor laser 100 of Embodiment 1, the hole current Ih that has leaked to the p-type semiconductor layer 7b, that is, the bypass current I2, is injected into the active layer 5 and contributes to the laser operation, and therefore, the characteristics do not vary, not depending on the amount of the bypass current I2 that has leaked to the p-type semiconductor layer 7b. Therefore, the semiconductor laser 100 of Embodiment 1 can reduce the characteristic variation with respect to the manufacturing variation of the p-type layer connecting portion, which is the portion where the side surface of the first p-type cladding layer 6 in the x-direction and the p-type semiconductor layer 7 are connected.

As described above, the semiconductor laser 100 of Embodiment 1 is a semiconductor laser including the ridge structure 16 formed on the n-type semiconductor substrate 1 and the buried layer 13 buried so as to cover both the sides of the ridge structure opposed to each other in the direction perpendicular to the extending direction of the ridge structure 16. The ridge structure 16 includes the n-type cladding layer (second n-type cladding layer 4), the active layer 5, and the p-type cladding layer (first p-type cladding layer 6), which are formed sequentially from the side of the n-type semiconductor substrate 1. The buried layer 13 includes the p-type semiconductor layer 7b in contact with both the side surfaces of the p-type cladding layer (first p-type cladding layer 6) and the active layer 5 in the ridge structure 16, and the semi-insulating layer 8, and the p-type semiconductor layer 7b is not in contact with the n-type cladding layer (second n-type cladding layer 4) of the ridge structure 16. In the semiconductor laser 100 of Embodiment 1, with the structure described above, since the p-type semiconductor layer 7b in contact with both the side surfaces of the p-type cladding layer (first p-type cladding layer 6) and the active layer 5 in the ridge structure 16 is not in contact with the n-type cladding layer (second n-type cladding layer 4) of the ridge structure 16, the reactive current that does not pass through the active layer 5 can be prevented, so that the optical output characteristics and the high-speed operation performance can be improved.

In the semiconductor laser 100 of Embodiment 1, the buried layer 13 may include the other p-type semiconductor layer 7a on the side of the n-type semiconductor substrate 1 of both the side surfaces of the n-type cladding layer (second n-type cladding layer 4) of the ridge structure 16. In this case, the separation portion 17 in which the p-type semiconductor layer 7b and the other p-type semiconductor layer 7a are separated from each other is formed on the side of the active layer 5 of both the side surfaces of the n-type cladding layer (second n-type cladding layer 4) of the ridge structure 16, and the semi-insulating layer 8 is embedded in the separation portion 17. In the semiconductor laser 100 of Embodiment 1, with the structure described above, even if the other p-type semiconductor layer 7a is present on the side of the n-type semiconductor substrate 1 of both the side surfaces of the n-type cladding layer (second n-type cladding layer 4) of the ridge structure 16, the p-type semiconductor layer 7b in contact with both the side surfaces of the p-type cladding layer (first p-type cladding layer 6) and the active layer 5 of the ridge structure 16 is not in contact with the n-type cladding layer (second n-type cladding layer 4) of the ridge structure 16, and thus the reactive current that does not pass through the active layer 5 can be prevented, so that the optical output characteristics and the high-speed operation performance can be improved.

### Embodiment 2

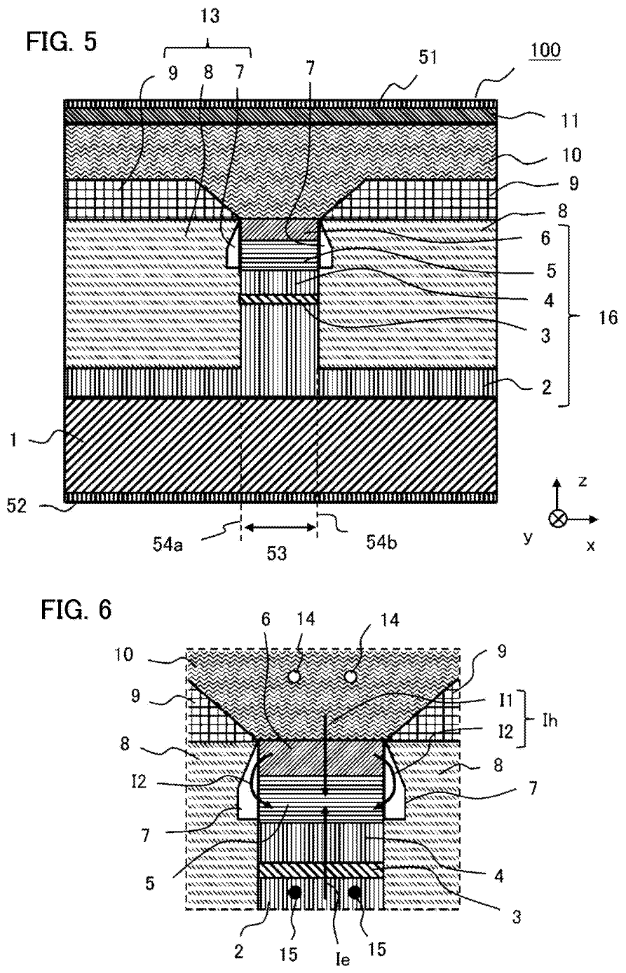

FIG. 5 is a diagram showing a cross-sectional structure of a semiconductor laser according to Embodiment 2, and FIG. 6 is an enlarged view of an area around an active layer of FIG. 5. The semiconductor laser 100 of Embodiment 2 is different from the semiconductor laser 100 of Embodiment 1 in that the p-type semiconductor layer 7 is in contact with the first p-type cladding layer 6 and the active layer 5 on both the side surfaces of the ridge structure 16, and the p-type semiconductor layer 7 is not in contact with both side surfaces of each layer on the side of the n-type semiconductor substrate 1 from the active layer 5 of the ridge structure 16. FIG. 5 and FIG. 6 show an example in which the p-type semiconductor layer 7 covers both side surfaces of the first p-type cladding layer 6 and the active layer 5 up to a specific position of the active layer, in both the side surfaces of the ridge structure 16. The specific position in FIG. 5 and FIG. 6 is a position farther from the side of the n-type semiconductor substrate 1 than the near end of the active layer 5 on the side of the n-type semiconductor substrate 1 and not reaching the interface initiating the quantum well structure 35, the interface being the near end of the quantum well structure 35 of the active layer 5 on the side of the n-type semiconductor substrate 1. That is, it is a position of an end portion including the near end of the quantum well structure 35 on the side of the n-type semiconductor substrate 1, that is, the position in the middle of the light confinement layer 31 of the active layer 5 on the side of the n-type semiconductor substrate 1. The p-type semiconductor layer 7 covers both side surfaces of the quantum well structure 35 of the active layer 5. Note that the specific position in the active layer 5 may be a position of the near end of the active layer 5 on the side of the n-type semiconductor substrate 1. The following description will focus on the differences from the semiconductor laser 100 of Embodiment 1.

In the semiconductor laser 100 of Embodiment 2, the semi-insulating layer 8 is in contact with both side surfaces of the first n-type cladding layer 2, the diffraction grating layer 3, and the second n-type cladding layer 4 on the side of the n-type semiconductor substrate 1 in the ridge structure 16. In the semiconductor laser 100 of Embodiment 2, as in the semiconductor laser 100 of Embodiment 1, when the semiconductor laser is driven, the holes 14 as the majority carriers in the contact layer 11 and the second p-type cladding layer 10 move to the side of the active layer 5, and the hole current Ih flows. The hole current Ih is composed of the main current I1 flowing from the first p-type cladding layer 6 to the active layer 5 and the bypass current I2 flowing from the first p-type cladding layer 6 to the active layer 5 via the p-type semiconductor layer 7. The bypass current I2 is a hole current component leaking from the first p-type cladding layer 6 to the p-type semiconductor layer 7. However, the bypass current I2 cannot flow through the side surfaces of the second n-type cladding layer 4 where the semi-insulating layer 8 exists, and flows in the direction of the valence band of the active layer 5 that is at a lower energy level than the valence band of the p-type semiconductor layer 7, and thus the bypass current I2 is injected into the active layer 5.

The semiconductor laser 100 of Embodiment 2 is similar to the semiconductor laser 100 of Embodiment 1 except that the p-type semiconductor layer 7 is not in contact with both the side surfaces of each layer on the side of the n-type semiconductor substrate 1 from the active layer 5 of the ridge structure 16, and therefore, the semiconductor laser 100 of Embodiment 2 has the same effect as the semiconductor laser 100 of Embodiment 1.

As described above, the semiconductor laser 100 of Embodiment 2 is a semiconductor laser including the ridge structure 16 formed on the n-type semiconductor substrate 1 and the buried layer 13 buried so as to cover both the sides of the ridge structure opposed to each other in the direction perpendicular to the extending direction of the ridge structure 16. The ridge structure 16 includes the n-type cladding layer (second n-type cladding layer 4), the active layer 5, and the p-type cladding layer (first p-type cladding layer 6), which are formed sequentially from the side of the n-type semiconductor substrate 1. The buried layer 13 includes the p-type semiconductor layer 7 in contact with both the side surfaces of the p-type cladding layer (first p-type cladding layer 6) and the active layer 5 in the ridge structure 16, and the semi-insulating layer 8. The p-type semiconductor layer 7 is not in contact with the n-type cladding layer (second n-type cladding layer 4) of the ridge structure 16, and the semi-insulating layer 8 is in contact with both the side surfaces of the n-type cladding layer (second n-type cladding layer 4) of the ridge structure 16. In the semiconductor laser 100 of Embodiment 2, with the structure described above, the p-type semiconductor layer 7 in contact with both the side surfaces of the p-type cladding layer (first p-type cladding layer 6) and the active layer 5 in the ridge structure 16 is not in contact with the n-type cladding layer (second n-type cladding layer 4) of the ridge structure 16, and thus the reactive current that does not pass through the active layer 5 can be prevented, so that the optical output characteristics and the high-speed operation performance can be improved.

### Embodiment 3

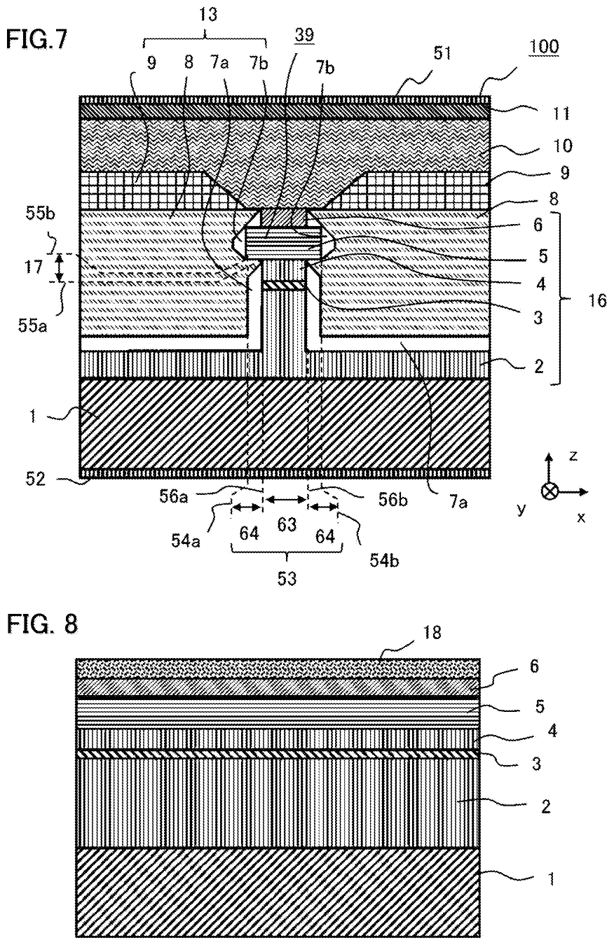

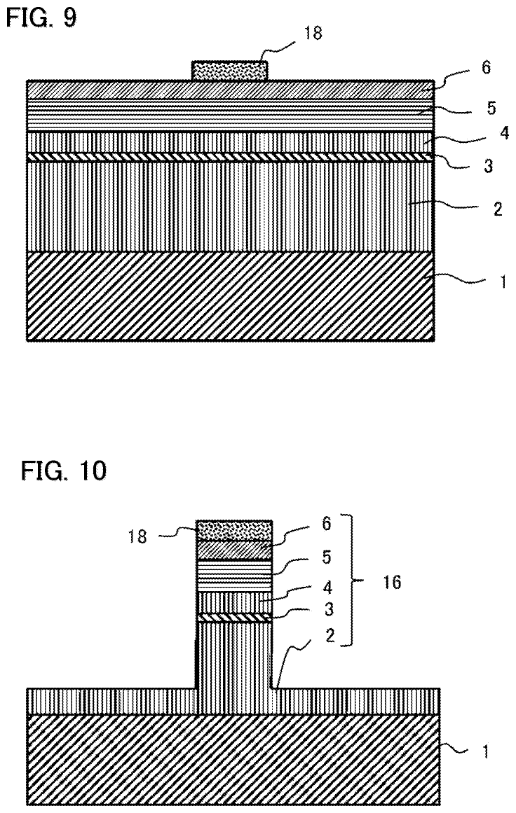

FIG. 7 is a diagram showing a cross-sectional structure of a semiconductor laser according to Embodiment 3. FIG. 8 to FIG. 13 are diagrams showing a method for manufacturing the semiconductor laser of FIG. 7. The semiconductor laser 100 of Embodiment 3 is different from the semiconductor laser 100 of Embodiment 1 in that the ridge structure 16 includes a ridge main portion 63 and a ridge extending portion 64 extending in the x-direction from both side surfaces of the ridge main portion 63, and the separating portion 17 is formed on the side of the n-type semiconductor substrate 1 of the ridge extending portion 64. The following description will focus on the differences from the semiconductor laser 100 of Embodiment 1.

In Embodiment 3, an example in which a ridge intermediate layer 39 with the ridge extending portion 64 formed is the active layer 5 will be described. In Embodiment 1, the case where the active layer 5 is made of a compound semiconductor containing A1 has been described as an example for the method for forming the p-type semiconductor layer 7a and the p-type semiconductor layer 7b separated from each other by interposing the separation portion 17 on both the side surfaces of the ridge structure 16. In Embodiment 3, a method for easily forming the p-type semiconductor layer 7a and the p-type semiconductor layer 7b separated from each other with the separation portion 17 interposed therebetween even when the active layer 5 does not contain A1 will be described.

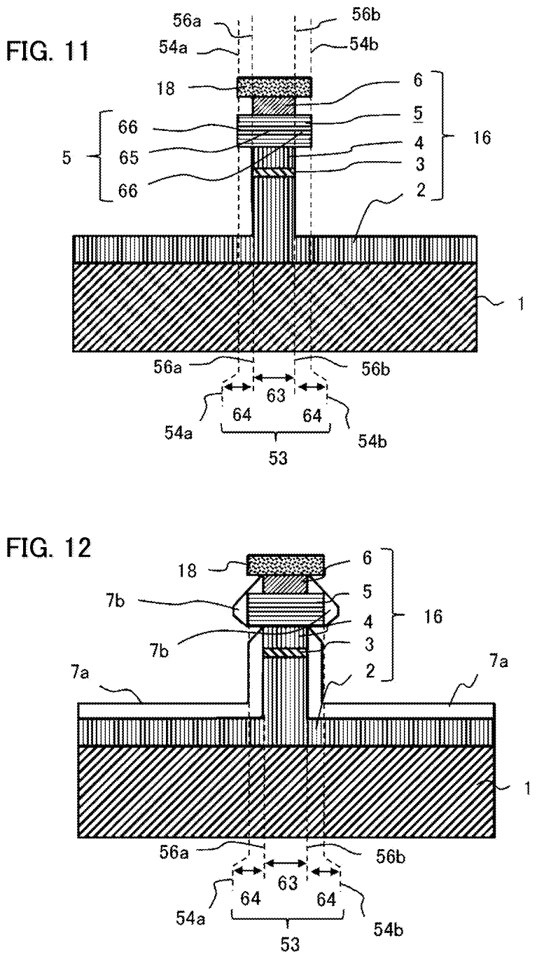

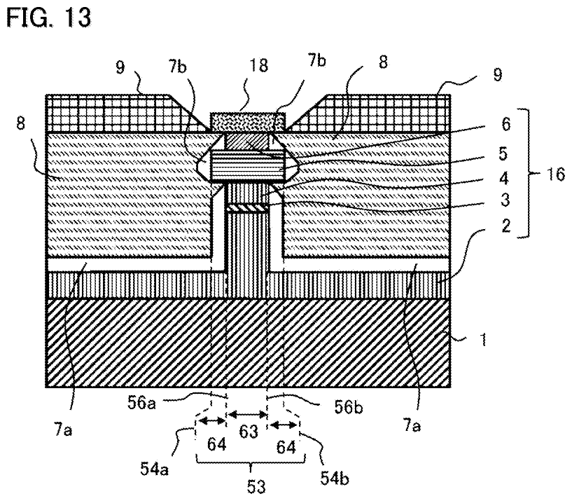

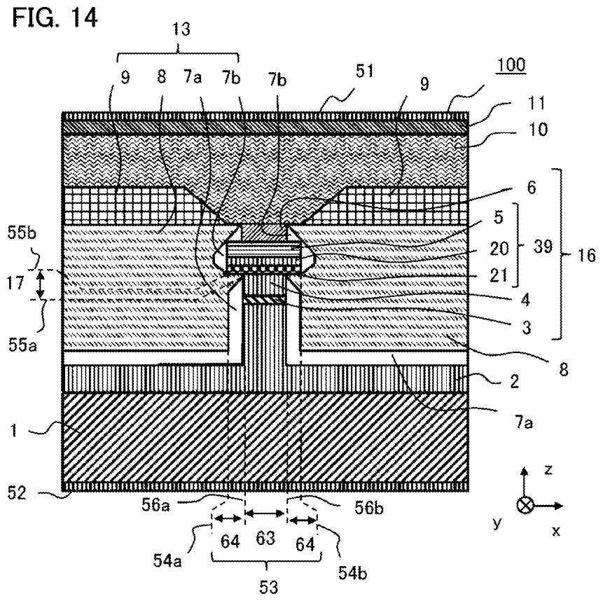

FIG. 8 to FIG. 10 are diagrams for describing a ridge structure forming step of forming a base of the ridge structure 16 on the n-type semiconductor substrate 1. FIG. 11 is a diagram for describing an extending portion forming step of forming the ridge extending portion 64 extending in the x-direction from both the side surfaces of the ridge structure 16 in the ridge intermediate layer 39 by etching layers on both sides of the base of the ridge structure 16, except for the ridge intermediate layer 39. FIG. 12 is a diagram for describing a p-type semiconductor layer forming step of forming the p-type semiconductor layers 7a and 7b so as to cover both the side surfaces of the ridge structure 16 and surfaces of the ridge extending portions 64 on the side opposite to the n-type semiconductor substrate 1. FIG. 13 is a diagram for describing a semi-insulating layer forming step of forming the semi-insulating layer 8 so as to cover the surfaces of the p-type semiconductor layers 7a and 7b and an exposed surface of the ridge extending portions 64 on the side of the n-type semiconductor substrate 1, and a step of forming the block layer 9.

On the surface of the n-type semiconductor substrate 1, the first n-type cladding layer 2, the diffraction grating layer 3, and on the upper surface thereof, that is, the surface on the positive side in the z-direction, the second n-type cladding layer 4, the active layer 5, and the first p-type cladding layer 6 are sequentially epitaxially grown by using a metal organic chemical vapor deposition (MOCVD) method. In other words, each of ridge semiconductor layers, which is a semiconductor layer in the ridge structure 16, is formed sequentially (ridge semiconductor layer forming step). An insulating film 18 such as a SiO₂ is formed on the upper surface, that is, the surface on the positive side in the z-direction. The semiconductor laser 100 shown in FIG. 7 is an example of a DFB-LD. When the semiconductor laser 100 is not the DFB-LD, the diffraction grating layer 3 is not formed.

As shown in FIG. 9, the insulating film 18 is processed by etching to leave a portion for forming the base of the ridge structure 16. The insulating film 18 is processed using a typical semiconductor photolithography process. As shown in FIG. 10, the first n-type cladding layer 2, the diffraction grating layer 3, the second n-type cladding layer 4, the active layer 5, and the first p-type cladding layer 6 are processed by etching using the insulating film 18 as a mask, thereby forming the base of the ridge structure 16 having both side surfaces in the x-direction exposed. A width in the x-direction of the base of the ridge structure 16 shown in FIG. 10 is the width in the x-direction of the ridge intermediate layer 39 of the final shape, the ridge intermediate layer having the ridge main portion 63 and the ridge extending portion 64 extending from both the sides in the x-direction of the ridge main portion 63 in the ridge structure 16. The ridge structure forming step of forming the base of the ridge structure 16 shown in FIG. 10 is a step of forming a ridge structure having the maximum width in the x-direction of the ridge structure 16 in the final shape in all potions between both side surfaces, that is, a ridge structure in the middle of the formation of the ridge structure 16.

Next, an extending portion forming step of forming the ridge extending portion 64 is performed. With respect to the base of the ridge structure 16 formed in the ridge structure forming step, each of the layers except for the active layer 5 is etched using an etchant, gas, or the like that does not etch the active layer 5, so that the active layer 5 has an active layer main portion 65 and an active layer extending portion 66 extending from both sides of the active layer main portion 65 in the x-direction; that is, the active layer extending portion 66 extending from both the side surfaces of the ridge main portion 63 in the x-direction, are formed in the active layer 5. The ridge extending portion 64 is between broken lines 54a and 56a and between broken lines 56b and 54b. A portion between the broken line 56a and the broken line 56b is the ridge main portion 63. In Embodiment 3, since the ridge intermediate layer 39 is only the active layer 5, the ridge main portion 63 is also the active layer main portion 65, and the ridge extending portion 64 is also the active layer extending portion 66. In the extending portion forming step, layers on both side surfaces of the base of the ridge structure 16 in the x-direction except for the ridge intermediate layer 39 are etched. The surface of the active layer extending portion 66 on the side of the n-type semiconductor substrate 1 in the z-direction faces the surface of the first n-type cladding layer 2 on the side opposite to the n-type semiconductor substrate 1, other than the ridge main portion 63, and thus the active layer extending portion 66 is a so-called overhang.

In the case where the material of the active layer 5 is InGaAsP or AlGaInAs, the active layer 5 can be shaped to have the active layer main portion 65 and the active layer extending portion 66 by using, for example, concentrated sulfuric acid for etching the InP layers. In the case where the material of the active layer 5 is AlGaInAs, the active layer 5 can be shaped to have the active layer main portion 65 and the active layer extending portion 66 by etching each layer of InP using hydrogen chloride gas in an apparatus for forming a film by the MOCVD method. Note that the length of the active layer extending portion 66 of the active layer 5 in the x-direction is set to a length at which a shadow effect can be obtained when the p-type semiconductor layer 7 is to be formed. Here, the shadow effect is an effect with which a material gas necessary for crystal growth is not sufficiently supplied to a surface of the ridge extending portion 64 extending from the ridge main portion 63 on the side of the n-type semiconductor substrate 1, that is, the surface on the negative side in the z-direction, and thus a crystal does not grow on the surface of the ridge extending portion 64 on the negative side in the z-direction.

Next, as shown in FIG. 12, a p-type semiconductor layer forming step of forming the p-type semiconductor layer 7 is performed. Crystal growth of p-type semiconductor layers 7a and 7b is performed by epitaxial growth using the MOCVD method on the ridge structure 16 of the final shape shown in FIG. 11. At this time, since the active layer extending portion 66 of the active layer 5 extends in the x-direction from the ridge main portion 63, the p-type semiconductor layers 7a and 7b can be prevented from growing on the surface of the active layer extending portion 66 on the side of the n-type semiconductor substrate 1 by utilizing the shadow effect of the active layer extending portion 66 being the ridge extending portion 64. By performing the p-type semiconductor layer forming step on the ridge structure 16 of the final shape shown in FIG. 11, the p-type semiconductor layers 7a and 7b can be formed so as to cover both the side surfaces of the ridge structure 16 and the surface of the ridge extending portion 64 on the side opposite to the n-type semiconductor substrate 1. That is, since the p-type semiconductor layer 7a and the p-type semiconductor layer 7b are separated from each other, the separation portion 17 that separates the p-type semiconductor layer 7a and the p-type semiconductor layer 7b can be formed on the side of the n-type semiconductor substrate 1 of the ridge extending portion 64, where the p-type semiconductor layers 7a and 7b are not to be formed.

After the p-type semiconductor layer forming step, as shown in FIG. 13, a semi-insulating layer forming step of forming the semi-insulating layer 8 and a step of forming the block layer 9 are performed. The semi-insulating layer 8 and the block layer 9 are epitaxially grown on an intermediate after the p-type semiconductor layer forming step shown in FIG. 12; that is, the semi-insulating layer 8 and the block layer 9 are formed. In the semi-insulating layer forming step, the semi-insulating layer 8 is formed so as to cover the surfaces of the p-type semiconductor layers 7a and 7b and the exposed surface of the ridge extending portion 64 on the side of the n-type semiconductor substrate 1, that is, the surface of the ridge extending portion 64 on the negative side in the z-direction. Thereafter, the block layer 9 is formed on the surface of the semi-insulating layer 8. Note that the semi-insulating layer forming step and the step of forming the block layer 9 are performed continuously to the p-type semiconductor layer forming step. That is, the p-type semiconductor layer forming step, the semi-insulating layer forming step, and the step of forming the block layer 9 are performed by the same apparatus. Next, the insulating film 18 is removed by using hydrofluoric acid, buffered hydrofluoric acid, or the like.

After the insulating film 18 is removed, crystal growth of the second p-type cladding layer 10 and the contact layer 11 is performed by the epitaxial growth. The second p-type cladding layer 10 is formed on the surface of the block layer 9 and the surface of the ridge structure 16, and the contact layer 11 is formed on the surface of the second p-type cladding layer 10. Thereafter, the anode electrode 51 is formed to be in contact with the contact layer 11, and the cathode electrode 52 is formed to be in contact with the rear surface of the n-type semiconductor substrate 1, that is, the surface on the negative side in the z-direction.

In Embodiment 3, the ridge extending portion 64 of the ridge intermediate layer 39 in the ridge structure 16, i.e., the active layer extending portion 66 of the active layer 5, is appropriately set to have a proper length in the x-direction, whereby the separation portion 17 for separating the p-type semiconductor layer 7a and the p-type semiconductor layer 7b can be easily formed on the negative side of the active layer extending portion 66 in the z-direction without adding a complicated step. The appropriate length of the active layer extending portion 66 in the x-direction is a length at which the shadow effect is obtained. Even in the case where the active layer 5 does not contain A1, the semiconductor laser 100 of Embodiment 3 can be manufactured to have the same structure as the semiconductor laser 100 of Embodiment 1, that is, the structure in which the p-type semiconductor layer 7a and the p-type semiconductor layer 7b separated from each other by the separation portion 17 interposed therebetween are formed on both the side surfaces of the ridge structure 16.

As described above, the semiconductor laser 100 of Embodiment 3 is a semiconductor laser including the ridge structure 16 formed on the n-type semiconductor substrate 1 and the buried layer 13 buried so as to cover both the sides of the ridge structure opposed to each other in the direction perpendicular to the extending direction of the ridge structure 16. The ridge structure 16 includes the n-type cladding layer (second n-type cladding layer 4), the active layer 5, and the p-type cladding layer (first p-type cladding layer 6), which are formed sequentially from the side of the n-type semiconductor substrate 1. The buried layer 13 includes the p-type semiconductor layer 7b in contact with both the side surfaces of the p-type cladding layer (first p-type cladding layer 6) and the active layer 5 in the ridge structure 16, and the semi-insulating layer 8. The p-type semiconductor layer 7b is not in contact with the n-type cladding layer (second n-type cladding layer 4) of the ridge structure 16. The buried layer 13 includes the other p-type semiconductor layer 7a on the side of the n-type semiconductor substrate 1 of both the side surfaces of the n-type cladding layer (second n-type cladding layer 4) of the ridge structure 16, and the separation portion 17 in which the p-type semiconductor layer 7b and the other p-type semiconductor layer 7a are separated from each other is formed on the side of the active layer 5 of both the side surfaces of the n-type cladding layer (second n-type cladding layer 4) of the ridge structure 16, and the semi-insulating layer 8 is embedded in the separation portion 17. The stacking direction of each layer of the ridge structure 16 is defined as the z-direction, the extending direction in which the ridge structure extends is defined as the y-direction, and the direction perpendicular to the z-direction and the y-direction is defined as the x-direction. The ridge structure 16 includes the ridge main portion 63 and the ridge extending portion 64 extending from both the side surfaces of the ridge main portion 63 in the x-direction. The ridge extending portion 64 is the active layer extending portion 66 in which the active layer 5 extends in the x-direction. The p-type semiconductor layer 7b is in contact with both the side surfaces of the p-type cladding layer (first p-type cladding layer 6) and the active layer 5 in the x-direction and the surface of the active layer extending portion 66 on the side opposite to the n-type semiconductor substrate 1, and the separation portion 17 is formed on the side of the n-type semiconductor substrate 1 of the active layer extending portion 66. In the semiconductor laser 100 of Embodiment 3, with the structure described above, even if the other p-type semiconductor layer 7a is present on the side of the n-type semiconductor substrate 1 of both the side surfaces of the n-type cladding layer (second n-type cladding layer 4) of the ridge structure 16, the p-type semiconductor layer 7b in contact with both the side surfaces of the p-type cladding layer (first p-type cladding layer 6) and the active layer 5 in the ridge structure 16 is not in contact with the n-type cladding layer (second n-type cladding layer 4) of the ridge structure 16, and thus the reactive current that does not pass through the active layer 5 can be prevented, so that the optical output characteristics and the high-speed operation performance can be improved.

The semiconductor laser manufacturing method for manufacturing the semiconductor laser 100 of Embodiment 3 is a semiconductor laser manufacturing method for manufacturing the semiconductor laser 100 including the ridge structure 16 formed on the n-type semiconductor substrate 1 and the buried layer 13 buried to cover both the sides of the ridge structure opposed to each other in the direction perpendicular to the extending direction of the ridge structure 16. The buried layer 13 includes the p-type semiconductor layers 7a and 7b and the semi-insulating layer 8. The stacking direction of each layer of the ridge structure 16 is defined as the z-direction, the extending direction in which the ridge structure 16 extends is defined as the y-direction, and the direction perpendicular to the z-direction and the y-direction is defined as the x-direction. The semiconductor laser manufacturing method of Embodiment 3 includes the ridge structure forming step of sequentially forming the n-type cladding layer (second n-type cladding layer 4), the ridge intermediate layer 39 including the active layer 5, and the p-type cladding layer (first p-type cladding layer 6) on the n-type semiconductor substrate 1, and of forming the ridge structure 16 including the n-type cladding layer (second n-type cladding layer 4), the ridge intermediate layer 39, and the p-type cladding layer (first p-type cladding layer 6) with both side surfaces thereof exposed by etching. The semiconductor laser manufacturing method of Embodiment 3 further includes the extending portion forming step of forming the ridge extending portion 64 extending in the x-direction from both the side surfaces of the ridge structure 16 (both the side surfaces of the ridge main portion 63 after the processing) in the ridge intermediate layer 39 by etching the layers except for the ridge intermediate layer 39 on both the side surfaces of the ridge structure 16 after the ridge structure forming step is performed. Furthermore, the semiconductor laser manufacturing method of Embodiment 3 includes the p-type semiconductor layer forming step of forming the p-type semiconductor layers 7a and 7b so as to cover both the side surfaces of the ridge structure 16 (both the side surfaces of the ridge main portion 63 and the ridge extending portion 64) and the surface of the ridge extending portion 64 opposite to the n-type semiconductor substrate 1, and the semi-insulating layer forming step of forming the semi-insulating layer 8 so as to cover the surfaces of the p-type semiconductor layers 7a and 7b and the exposed surface of the ridge extending portion 64 on the side of the n-type semiconductor substrate 1. The semiconductor laser manufacturing method for manufacturing the semiconductor laser 100 of Embodiment 3 can manufacture the semiconductor laser 100 in which the p-type semiconductor layer 7b in contact with both the side surfaces of the p-type cladding layer (first p-type cladding layer 6) and the active layer 5 in the ridge structure 16 is not in contact with the n-type cladding layer (second n-type cladding layer 4) of the ridge structure 16 even when the p-type semiconductor layer 7a is present on the side of the n-type semiconductor substrate 1 of both the side surfaces of the n-type cladding layer (second n-type cladding layer 4) of the ridge structure 16. Therefore, the semiconductor laser 100 manufactured by the semiconductor laser manufacturing method of Embodiment 3 can prevent the reactive current that does not pass through the active layer 5, so that the optical output characteristics and the high-speed operation performance can be improved.

### Embodiment 4

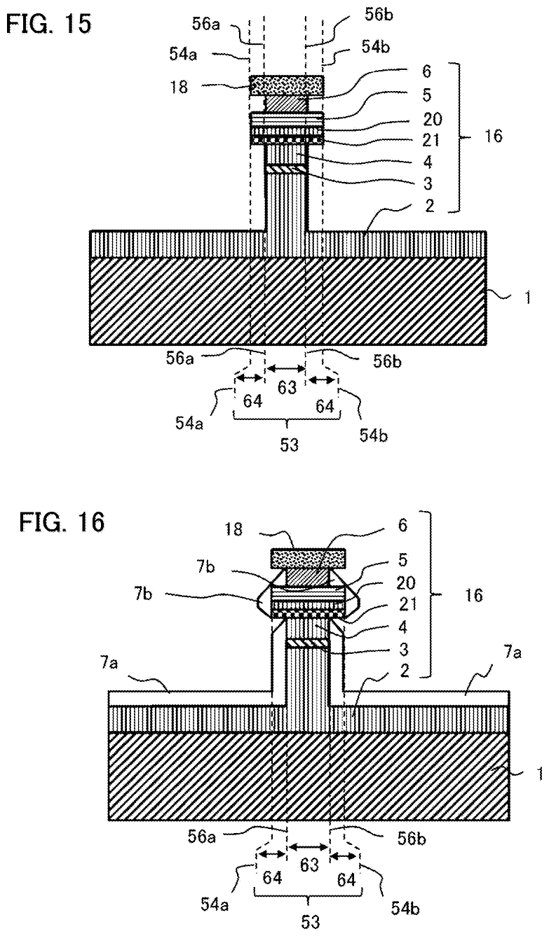

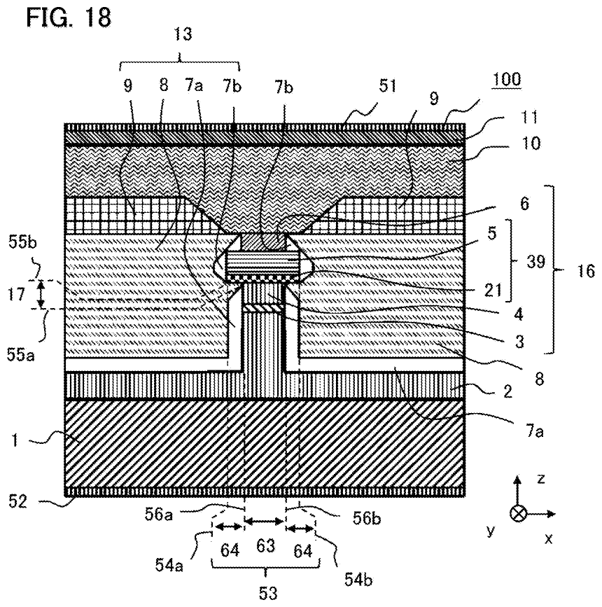

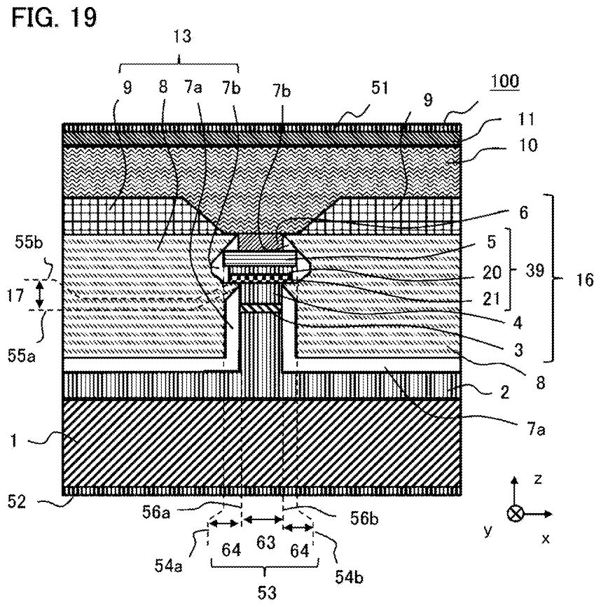

FIG. 14 is a diagram showing a cross-sectional structure of a first semiconductor laser according to Embodiment 4. FIG. 15 to FIG. 17 are diagrams showing a method for manufacturing the semiconductor laser of FIG. 14. FIG. 18 is a diagram showing a cross-sectional structure of a second semiconductor laser according to Embodiment 4, and FIG. 19 is a diagram showing a cross-sectional structure of a third semiconductor laser according to Embodiment 4. The semiconductor laser 100 of Embodiment 4 is different from the semiconductor laser 100 of Embodiment 3 in that the ridge intermediate layer 39 with the ridge extending portion 64 in the ridge structure 16 includes an extending portion base layer 21 and the active layer 5. The following description will focus on the differences from the semiconductor laser 100 of Embodiment 3.

The first and third semiconductor lasers 100 of Embodiment 4 are examples in which the ridge intermediate layer 39 with the ridge extending portion 64 includes the extending portion base layer 21, a third n-type cladding layer 20, and the active layer 5. The second semiconductor laser 100 of Embodiment 4 is an example in which the ridge intermediate layer 39 with the ridge extending portion 64 includes the extending portion base layer 21 and the active layer 5. The ridge structure 16 in the first semiconductor laser 100 of Embodiment 4 includes the extending portion base layer 21 of AlGaInAs or InGaAsP and the third n-type cladding layer 20 of n-type InP formed sequentially from the side of the n-type semiconductor substrate 1 between the second n-type cladding layer 4 and the active layer 5. As in Embodiment 3, in the case where the material of the active layer 5 is InGaAsP or AlGaInAs, the extending portion base layer 21 is made of the same material as the active layer 5, and thus the ridge extending portion 64 can be formed using an etching solution such as concentrated sulfuric acid having an etching rate lower than the etching rate of the InP layers. In addition, in the case where the material of the active layer 5 and the extending portion base layer 21 is AlGaInAs, the ridge extending portion 64 can be formed using hydrogen chloride gas. By making the third n-type cladding layer 20 interposed between the active layer 5 and the extending portion base layer 21 a thin film, the third n-type cladding layer 20 is not etched, and the third n-type cladding layer 20 can be left as a part of the ridge extending portion 64 as shown in FIG. 15. The minimum thickness of the third n-type cladding layer 20 is equal to or larger than the crystal lattice, and is, for example, 1 nm. The thickness at which the third n-type cladding layer 20 is not etched depends on the etching material to be used, the state of the surface of the semiconductor layer during etching, and the like. The third n-type cladding layer 20 should have a film thickness that remains even after the ridge extending portion 64 is formed by etching, and therefore, the third n-type cladding layer 20 does not need to be maximized in the film thickness. The maximum thickness of the third n-type cladding layer 20 that is not etched is confirmed as the thickness remained after etching by an experiment, if necessary.

The extending portion base layer 21 may be made of a material other than AlGaInAs and InGaAsP as long as the material is not etched by an etching solution or an etching gas for forming the ridge extending portion 64. Further, in the ridge intermediate layer 39, the active layer 5 and the extending portion base layer 21 may be in direct contact with each other, and the active layer 5 and the extending portion base layer 21 in the ridge intermediate layer 39 may have different lengths in the x-direction. The second semiconductor laser 100 of Embodiment 4 shown in FIG. 18 is an example in which the active layer 5 and the extending portion base layer 21 are in direct contact with each other in the ridge intermediate layer 39. The third semiconductor laser 100 of Embodiment 4 shown in FIG. 19 is an example in which the active layer 5 and the extending portion base layer 21 in the ridge intermediate layer 39 have different lengths in the x-direction. FIG. 19 shows an example in which the extending portion base layer 21 is shorter than the active layer 5, and thus the third n-type cladding layer 20 has the same length in the x-direction as the extending portion base layer 21. In any of the first to third semiconductor lasers 100 of Embodiment 4, the ridge extending portion 64 can be formed by etching.

In the case where the ridge intermediate layer 39 includes the extending portion base layer 21, the third n-type cladding layer 20, and the active layer 5, in the ridge semiconductor layer forming step, the extending portion base layer 21, the third n-type cladding layer 20, the active layer 5, and the first p-type cladding layer 6 are sequentially epitaxially grown on the surface of the second n-type cladding layer 4 to form each of the ridge semiconductor layers, which are the semiconductor layers of the ridge structure 16. In the case where the ridge intermediate layer 39 includes the extending portion base layer 21 and the active layer 5, in the ridge semiconductor layer forming step, the extending portion base layer 21, the active layer 5, and the first p-type cladding layer 6 are sequentially epitaxially grown on the surface of the second n-type cladding layer 4 to form each of the ridge semiconductor layers.

In the ridge structure forming step, the base of the ridge structure 16 is formed using the insulating film 18 as a mask, and in the extending portion forming step, the layers except for the ridge intermediate layer 39 are etched from the x-direction with respect to the base of the ridge structure 16, thereby forming the ridge structure 16 including the ridge main portion 63 and the ridge extending portion 64. FIG. 15 shows an intermediate of the first semiconductor laser 100 of Embodiment 4 after the extending portion forming step.

In the p-type semiconductor layer forming step, the p-type semiconductor layers 7a and 7b are formed on the ridge structure 16 of the final shape shown in FIG. 15 so as to cover both the side surfaces of the ridge structure 16, and the surface of the ridge extending portion 64 on the side opposite to the n-type semiconductor substrate 1. FIG. 16 shows an intermediate of the first semiconductor laser 100 of Embodiment 4 after the p-type semiconductor layer forming step. Since the ridge structure 16 includes the ridge extending portion 64 extending from the ridge main portion 63, the separation portion 17 that separates the p-type semiconductor layer 7a and the p-type semiconductor layer 7b from each other can be formed on the surface of the ridge extending portion 64 on the negative side in the z-direction by the shadow effect.

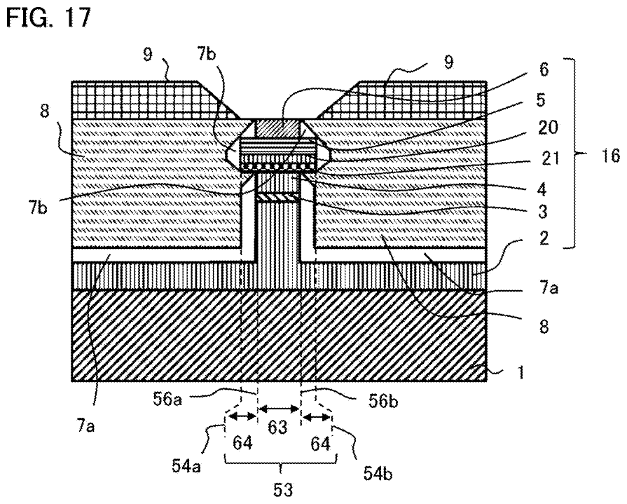

In the semi-insulating layer forming step, the semi-insulating layer 8 is formed on the intermediate of the semiconductor laser 100 shown in FIG. 16, and in the subsequent step to form the block layer 9, the block layer 9 is formed on the surface of the semi-insulating layer 8. FIG. 17 shows an intermediate of the first semiconductor laser 100 of Embodiment 4 in which the semi-insulating layer forming step and the step of forming the block layer 9 are completed and the insulating film 18 is removed.

Thereafter, as described in Embodiment 3, the second p-type cladding layer 10 and the contact layer 11 are formed on the surface of the block layer 9 and the surface of the ridge structure 16 in the z-direction. Specifically, the second p-type cladding layer 10 is formed on the surface of the block layer 9 and the surface of the ridge structure 16, and the contact layer 11 is formed on the surface of the second p-type cladding layer 10. Then, the anode electrode 51 is formed to be in contact with the contact layer 11, and the cathode electrode 52 is formed to be in contact with the rear surface of the n-type semiconductor substrate 1, that is, the surface on the negative side in the z-direction.

As in the semiconductor laser 100 of Embodiment 3, even when the active layer 5 does not contain A1, the semiconductor laser 100 of Embodiment 4 can be manufactured to have the same structure as the semiconductor laser 100 of Embodiment 1, that is, the structure in which the p-type semiconductor layer 7a and the p-type semiconductor layer 7b separated from each other by the separation portion 17 interposed therebetween are formed on both the side surfaces of the ridge structure 16. Therefore, the semiconductor laser 100 of Embodiment 4 can reduce the reactive current that does not pass through the active layer 5 and improve the optical output characteristics and the high-speed operation performance, as compared with the semiconductor laser of the comparative example shown in FIG. 4.

In the first semiconductor laser 100 of Embodiment 4, since the third n-type cladding layer 20 is provided between the active layer 5 and the extending portion base layer 21, the bypass current I2 of the holes 14 flowing through the p-type semiconductor layer 7 is injected into the third n-type cladding layer 20 and the extending portion base layer 21 as well as the active layer 5. The holes 14 and the electrons 15 are recombined in the third n-type cladding layer 20 and the extending portion base layer 21. Note that the valence band energy level of the extending portion base layer 21 is higher than the valence band energy level of the p-type semiconductor layer 7b, as will be described later. Therefore, due to the energy barrier between the extending portion base layer 21 and the p-type semiconductor layer 7b, the number of holes 14 moving from the p-type semiconductor layer 7b to the extending portion base layer 21 is extremely smaller than the number of holes 14 moving from the p-type semiconductor layer 7b to the third n-type cladding layer 20. Therefore, in the first semiconductor laser 100 of Embodiment 4, although the reactive current is generated to some extent as compared with the semiconductor laser 100 of Embodiment 3, the reactive current can be reduced as compared with the semiconductor laser of the comparative example.

In the second semiconductor laser 100 of Embodiment 4, since the third n-type cladding layer 20 is not provided between the active layer 5 and the extending portion base layer, the reactive current that does not pass through the active layer 5 can be reduced as compared with the first semiconductor laser 100 of Embodiment 4.

### Embodiment 5

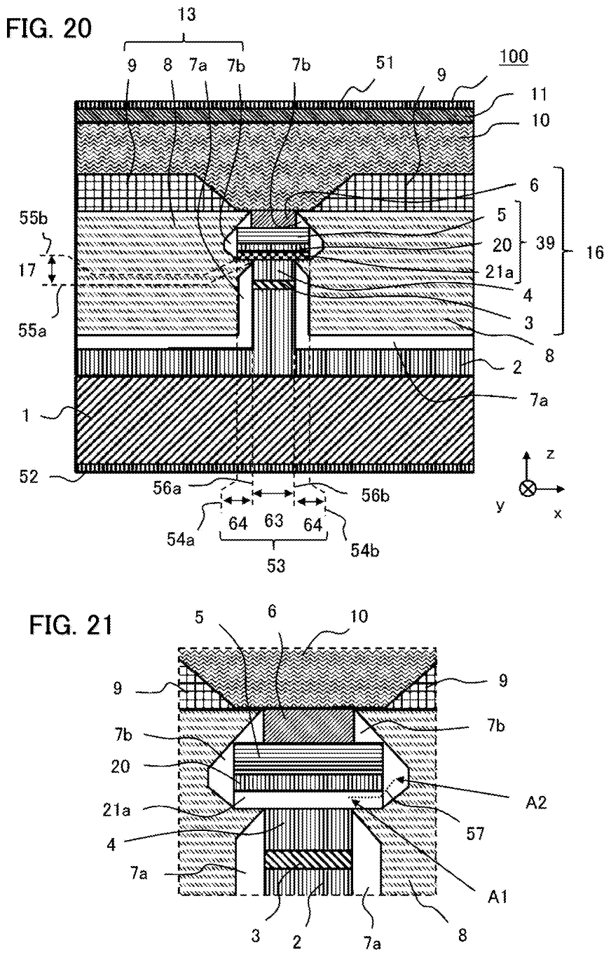

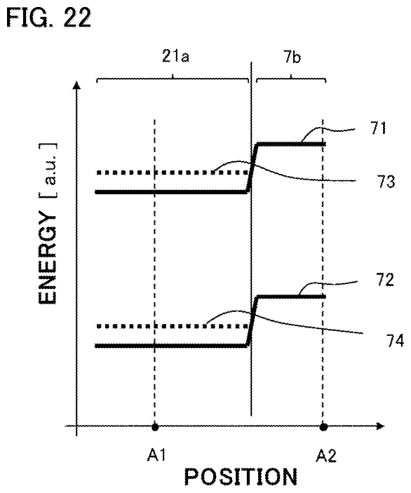

FIG. 20 is a diagram showing a cross-sectional structure of a semiconductor laser according to Embodiment 5. FIG. 21 is an enlarged view of an area around an active layer of FIG. 20, and FIG. 22 is a diagram showing energy bands of the extending portion base layer and the p-type semiconductor layer in FIG. 21. The semiconductor laser 100 of Embodiment 5 is different from the semiconductor laser 100 of Embodiment 4 in that the valence band energy level of an extending portion base layer 21a of the ridge intermediate layer 39 is higher than that of the extending portion base layer 21 of Embodiment 4 with respect to the valence band energy level of the p-type semiconductor layer 7b. The following description will focus on the differences from the semiconductor laser 100 of Embodiment 4.

The energy bands shown in FIG. 22 are energy bands between a position A1 of the extending portion base layer 21a and a position A2 of the p-type semiconductor layer 7b that are shown in FIG. 21. In FIG. 21, the pattern of the extending portion base layer 21a is omitted. In FIG. 22, the horizontal axis represents a position, and the vertical axis represents energy [a.u. (arbitrary unit)]. Along with conduction band energy 71 and valence band energy 72 indicated by solid lines, conduction band energy 73 and valence band energy 74 in the extending portion base layer 21 of Embodiment 4 are indicated by broken lines. The conduction band energy and the valence band energy of the third n-type cladding layer 20 are higher than the conduction band energy 73 and the valence band energy 74 indicated by the broken lines; that is, they are on the upper side (y-axis positive side) in FIG. 22, and the energy barrier that is the energy difference between the third n-type cladding layer 20 and the p-type semiconductor layer 7b is smaller than the energy barrier between the extending portion base layer 21 or 21a and the p-type semiconductor layer 7b. The bypass current I2 of the holes 14 that leaks to the p-type semiconductor layer 7b flows on the valence-band side of the p-type semiconductor layer 7b. Therefore, the bypass current I2 of the holes 14 flowing from the p-type semiconductor layer 7b to the ridge intermediate layer 39 mainly flows to the third n-type cladding layer 20.

In order to prevent the bypass current I2 of the holes 14 that leaks to the p-type semiconductor layer 7b from flowing into the extending portion base layer 21 of Embodiment 4, it is necessary to increase the valence band energy level of the extending portion base layer 21 with respect to the valence band energy level of the p-type semiconductor layer 7b. Note that energy on the positive side in the y-axis in FIG. 22 is small with respect to the holes 14. In order to achieve this, the extending portion base layer 21 of Embodiment 4 may be made of an n-type highly-doped material, or the extending portion base layer 21 of Embodiment 4 may be replaced with an n-type AlInAs layer having a larger band gap than the p-type semiconductor layer 7b. The extending portion base layer 21a should be an n-type AlGaInAs layer or an n-type AlInAs layer, which is an n-type semiconductor layer.

In the semiconductor laser 100 of Embodiment 5, the valence band energy level in the extending portion base layer 21a of the ridge intermediate layer 39 is higher than that of the extending portion base layer 21 of Embodiment 4, and thus an energy barrier higher than that of the extending portion base layer 21 of Embodiment 4 exists with respect to the p-type semiconductor layer 7b. Therefore, the movement of the holes 14 to the extending portion base layer 21a is reduced, and the recombination with the electrons 15 in the extending portion base layer 21a is reduced. Therefore, the semiconductor laser 100 of Embodiment 5 can reduce the reactive current that does not pass through the active layer 5 more than the semiconductor laser 100 of Embodiment 4.

### Embodiment 6

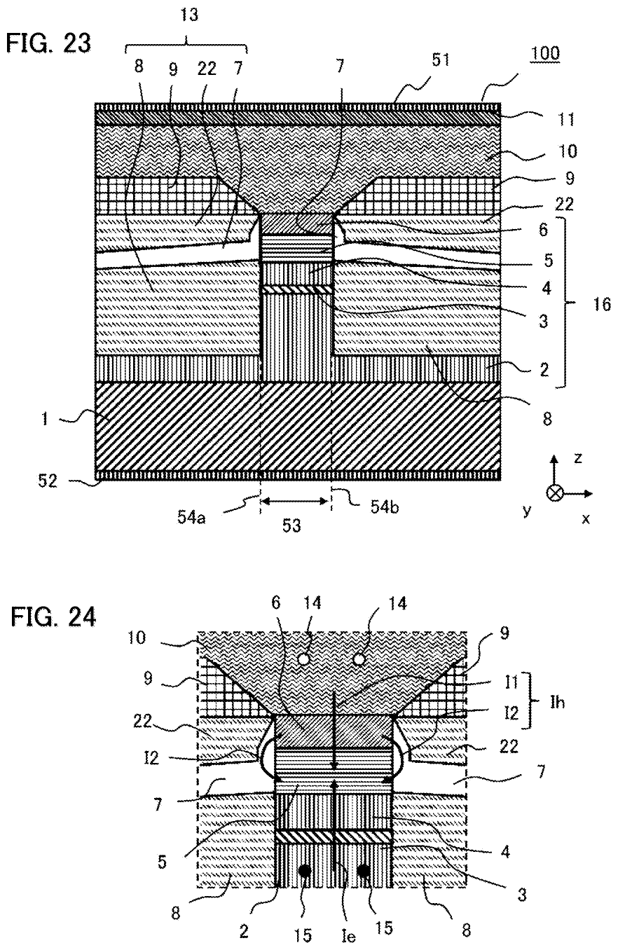

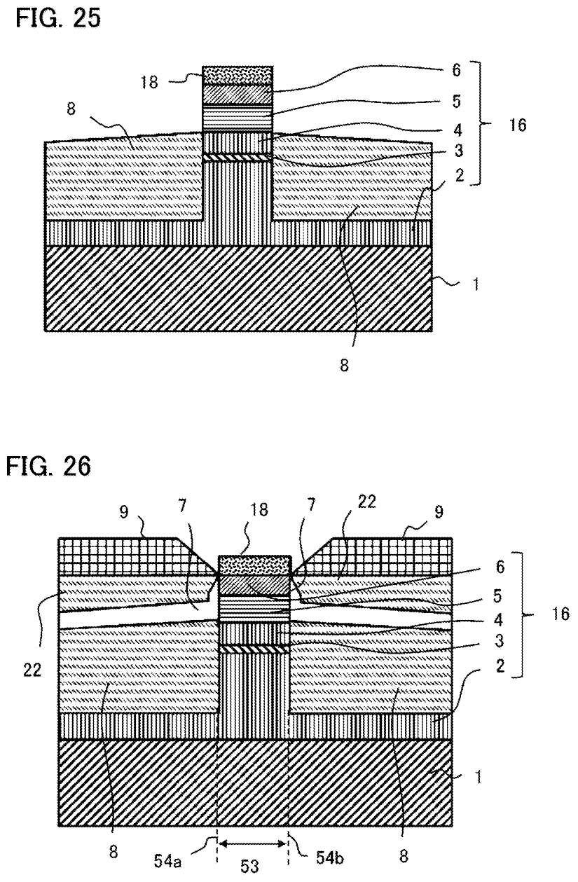

FIG. 23 is a diagram showing a cross-sectional structure of a semiconductor laser according to Embodiment 6, and FIG. 24 is an enlarged view of an area around an active layer of FIG. 23. FIG. 25 and FIG. 26 are diagrams showing a method for manufacturing the semiconductor laser of FIG. 23. The semiconductor laser 100 of Embodiment 6 is a semiconductor laser that can easily achieve the characteristic structure of the semiconductor laser 100 of Embodiment 2, that is, the structure in which the p-type semiconductor layer 7 is in contact with only the first p-type cladding layer 6 and the active layer 5 on both the side surfaces of the ridge structure 16. The semiconductor laser 100 of Embodiment 6 is different from the semiconductor laser 100 of Embodiment 2 in that the buried layer 13 includes the semi-insulating layer 8, the p-type semiconductor layer 7, a semi-insulating layer 22, and the block layer 9, and the p-type semiconductor layer 7 is formed on the surface of the semi-insulating layer 8 opposite to the n-type semiconductor substrate 1 so as to spread in a direction away from the ridge structure 16. The following description will focus on the differences from the semiconductor laser 100 of Embodiment 2.

In the semiconductor laser 100 of Embodiment 6, as in the semiconductor laser 100 of Embodiment 2, when the semiconductor laser is driven, the holes 14 as the majority carriers in the contact layer 11 and the second p-type cladding layer 10 move to the side of the active layer 5, and the hole current Ih flows. The hole current Ih is composed of the main current I1 flowing from the first p-type cladding layer 6 to the active layer 5 and the bypass current I2 flowing from the first p-type cladding layer 6 to the active layer 5 via the p-type semiconductor layer 7. The bypass current I2 is the hole current component leaking from the first p-type cladding layer 6 to the p-type semiconductor layer 7. In the portion where the p-type semiconductor layer 7 spreads in the direction away from the ridge structure 16, that is, in the x-direction, the p-type semiconductor layer 7 is interposed between the semi-insulating layer 8 and the semi-insulating layer 22, and the electrons 15 do not exist in the semi-insulating layer 8 and the semi-insulating layer 22, and thus, do not recombine with the holes 14. Therefore, the bypass current I2 cannot flow through the side surfaces of the second n-type cladding layer 4 where the semi-insulating layer 8 exists, and flows in the direction of the valence band of the active layer 5 that is at a lower energy level than the valence band of the p-type semiconductor layer 7, so that the bypass current I2 is injected into the active layer 5. Therefore, in the semiconductor laser 100 of Embodiment 6, no reactive current is generated as in the semiconductor laser 100 of Embodiment 2.

A semiconductor laser manufacturing method for manufacturing the semiconductor laser 100 of Embodiment 6 will be described. The steps up to the ridge structure forming step of forming the ridge structure 16 are the same as the steps up to the ridge structure forming step described in Embodiment 3. Since the semiconductor laser 100 of Embodiment 6 does not have the ridge extending portion 64, a first semi-insulating layer forming step of forming the semi-insulating layer 8 on the side of the n-type semiconductor substrate 1 of both the side surfaces of the ridge structure 16 is performed after the ridge structure forming step. In the first semi-insulating layer forming step, the semi-insulating layer 8 is formed by the epitaxial growth so as to cover both the side surfaces of the ridge structure 16 from the side of the n-type semiconductor substrate 1 up to the specific position of the active layer 5. Here, the specific position of the active layer 5 is a position (first specific position) of the near end of the active layer 5 on the side of the n-type semiconductor substrate 1 or a position (second specific position) farther from the side of the n-type semiconductor substrate 1 than the near end of the active layer 5 and not reaching the near end of the quantum well structure 35 of the active layer 5 on the side of the n-type semiconductor substrate 1. FIG. 25 shows an intermediate of the semiconductor laser 100 after the first semi-insulating layer forming step. By appropriately setting the epitaxial growth conditions of the semi-insulating layer 8, the semi-insulating layer 8 can be formed to cover the surface on the positive side in the z-direction and both the side surfaces of the ridge structure 16 in the x-direction in the first n-type cladding layer 2, and both side surfaces of the diffraction grating layer 3 and the second n-type cladding layer 4 in the x-direction, and thus the semi-insulating layer 8 can be formed to cover both the side surfaces in the ridge structure 16 from the side of the n-type semiconductor layer 1 up to the specific position of the active layer 5.

After the first semi-insulating layer forming step, the p-type semiconductor layer forming step of forming the p-type semiconductor layer 7 and a second semi-insulating layer forming step of forming the semi-insulating layer 22 are performed. In the p-type semiconductor layer forming step, the p-type semiconductor layer 7 is formed by the epitaxial growth so as to cover the surface of the semi-insulating layer 8 and both the side surfaces exposed in the ridge structure 16 from the specific position of the active layer 5 up to the far end opposite to the n-type semiconductor substrate 1. In the second semi-insulating layer forming step, the semi-insulating layer 22 is formed by the epitaxial growth so as to cover the p-type semiconductor layer 7.

After the second semi-insulating layer forming step, the block layer 9 is formed by the epitaxial growth. FIG. 26 shows an intermediate of the semiconductor laser 100 of Embodiment 6 after the second semi-insulating layer forming step and the step of forming the block layer 9 are completed.

Thereafter, as described in Embodiment 3, the insulating film 18 is removed, and the second p-type cladding layer 10 and the contact layer 11 are formed on the surface of the block layer 9 and the surface of the ridge structure 16 in the z-direction. Specifically, the second p-type cladding layer 10 is formed on the surface of the block layer 9 and the surface of the ridge structure 16, and the contact layer 11 is formed on the surface of the second p-type cladding layer 10. Then, the anode electrode 51 is formed to be in contact with the contact layer 11, and the cathode electrode 52 is formed to be in contact with the rear surface of the n-type semiconductor substrate 1, that is, the surface on the negative side in the z-direction.

The semiconductor laser 100 of Embodiment 6 is the same as the semiconductor laser 100 of Embodiment 2 except that the p-type semiconductor layer 7 extends in a direction away from the ridge structure 16 on the surface of the semi-insulating layer 8 opposite to the n-type semiconductor substrate 1 and the p-type semiconductor layer 7 is interposed between the semi-insulating layer 8 and the semi-insulating layer 22, so that the same effect as in the semiconductor laser 100 of Embodiment 2 can be obtained.

Note that, in the method for manufacturing the semiconductor laser 100 of Embodiment 2 shown in FIG. 5, for example, a step of etching the p-type semiconductor layer 7 on the surface of the semi-insulating layer 8 on the positive side in the z-direction is added after the p-type semiconductor layer forming step in the method for manufacturing the semiconductor laser 100 of Embodiment 6, and then the second semi-insulating layer forming step and the subsequent steps are performed. The etching of the p-type semiconductor layer 7 is performed by using a semiconductor photolithography process. The semi-insulating layer 8 and the semi-insulating layer 22 are integrated, and thus can be referred to as an integrated semi-insulating layer 8. The method for manufacturing the semiconductor laser 100 of Embodiment 2 is more complicated than the method for manufacturing the semiconductor laser 100 of Embodiment 6. Therefore, the semiconductor laser 100 of Embodiment 6 can easily achieve the characteristic structure of the semiconductor laser 100 of Embodiment 2, that is, the structure in which the p-type semiconductor layer 7 is in contact with only the first p-type cladding layer 6 and the active layer 5 on both the side surfaces of the ridge structure 16.

As described above, the semiconductor laser 100 of Embodiment 6 is a semiconductor laser including the ridge structure 16 formed on the n-type semiconductor substrate 1 and the buried layer 13 buried so as to cover both the sides of the ridge structure opposed to each other in the direction perpendicular to the extending direction of the ridge structure 16. The ridge structure 16 includes the n-type cladding layer (second n-type cladding layer 4), the active layer 5, and the p-type cladding layer (first p-type cladding layer 6), which are formed sequentially from the side of the n-type semiconductor substrate 1. The buried layer 13 includes the p-type semiconductor layer 7 in contact with both the side surfaces of the p-type cladding layer (first p-type cladding layer 6) and the active layer 5 in the ridge structure 16, the semi-insulating layer 8, and the semi-insulating layer 22. The p-type semiconductor layer 7 is not in contact with the n-type cladding layer (second n-type cladding layer 4) of the ridge structure 16, and the semi-insulating layer 8 is in contact with both the side surfaces of the n-type cladding layer (second n-type cladding layer 4) of the ridge structure 16. In addition, the p-type semiconductor layer 7 is formed on the surface of the semi-insulating layer 8 on the side opposite to the n-type semiconductor substrate 1 so as to spread in the direction away from the ridge structure 16. The semi-insulating layer 22 covers the surface of the p-type semiconductor layer 7 on the side opposite to the n-type semiconductor substrate 1 and the surface on the side of the ridge structure 16. In the semiconductor laser 100 of Embodiment 6, with the structure described above, the p-type semiconductor layer 7 in contact with both the side surfaces of the p-type cladding layer (first p-type cladding layer 6) and the active layer 5 in the ridge structure 16 is not in contact with the n-type cladding layer (second n-type cladding layer 4) of the ridge structure 16, and thus the reactive current that does not pass through the active layer 5 can be prevented, so that the optical output characteristics and the high-speed operation performance can be improved.

The semiconductor laser manufacturing method for manufacturing the semiconductor laser 100 of Embodiment 6 is a semiconductor laser manufacturing method for manufacturing the semiconductor laser 100 provided with the ridge structure 16 including the active layer 5 formed on the n-type semiconductor substrate 1, and the buried layer 13 buried to cover both the sides of the ridge structure opposed to each other in the direction perpendicular to the extending direction of the ridge structure 16. The buried layer 13 includes the first semi-insulating layer (semi-insulating layer 8), the p-type semiconductor layer 7, and the second semi-insulating layer (semi-insulating layer 22). The specific position of the active layer is set to a position of the near end of the active layer 5 on the side of the n-type semiconductor substrate 1 or a position farther from the side of the n-type semiconductor substrate 1 than the near end of the active layer 5 and not reaching the near end of the quantum well structure 35 of the active layer 5 on the side of the n-type semiconductor substrate 1. The semiconductor laser manufacturing method of Embodiment 6 includes the ridge structure forming step of sequentially forming the n-type cladding layer (second n-type cladding layer 4), the active layer 5, and the p-type cladding layer (first p-type cladding layer 6) on the n-type semiconductor substrate 1, and of forming the ridge structure 16 including the n-type cladding layer (second n-type cladding layer 4), the active layer 5, and the p-type cladding layer (first p-type cladding layer 6), with both the side surfaces exposed by etching. The semiconductor laser manufacturing method of Embodiment 6 further includes the first semi-insulating layer forming step of forming the first semi-insulating layer (semi-insulating layer 8) so as to cover both the side surfaces of the ridge structure 16 from the side of the n-type semiconductor substrate 1 to the specific position of the active layer 5, the p-type semiconductor layer forming step of forming the p-type semiconductor layer 7 so as to cover the surface of the first semi-insulating layer (semi-insulating layer 8) and both the side surfaces exposed in the ridge structure 16 from the specific position of the active layer 5 up to the far end opposite to the n-type semiconductor substrate 1, and the second semi-insulating layer forming step of forming the second semi-insulating layer (semi-insulating layer 22) so as to cover the p-type semiconductor layer 7. The semiconductor laser manufacturing method for manufacturing the semiconductor laser 100 of Embodiment 6 can manufacture the semiconductor laser 100 in which the p-type semiconductor layer 7 in contact with both the side surfaces of the p-type cladding layer (first p-type cladding layer 6) and the active layer 5 in the ridge structure 16 is not in contact with the n-type cladding layer (second n-type cladding layer 4) of the ridge structure 16. Therefore, the semiconductor laser 100 manufactured by the semiconductor laser manufacturing method of Embodiment 6 can prevent the reactive current that does not pass through the active layer 5, and can improve the optical output characteristics and the high-speed operation performance.

### Embodiment 7

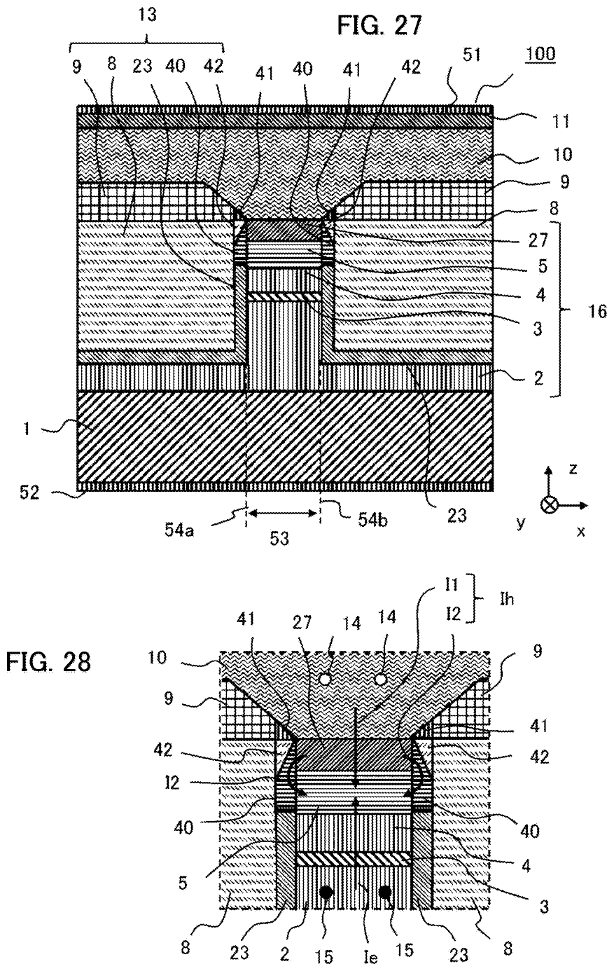

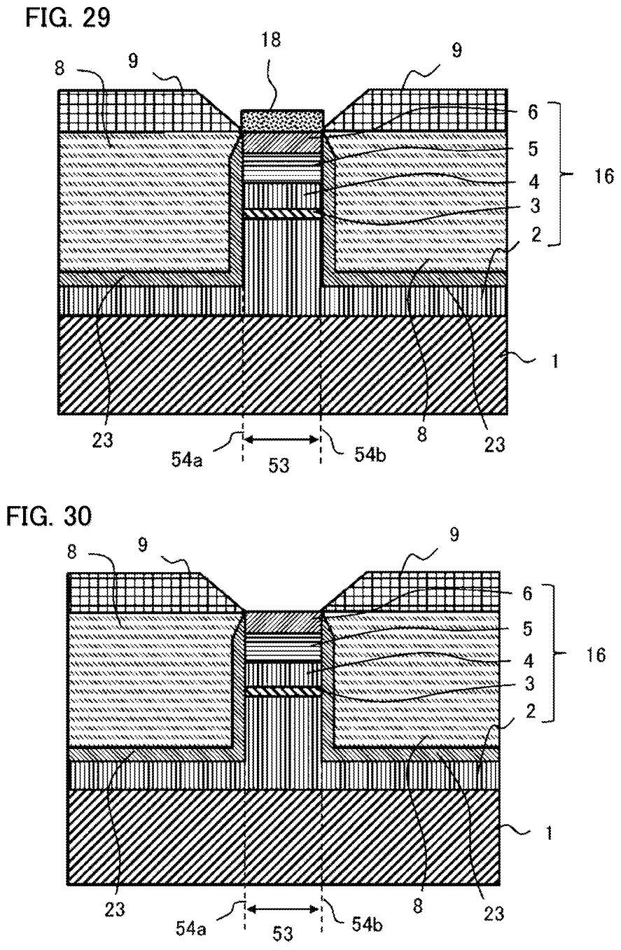

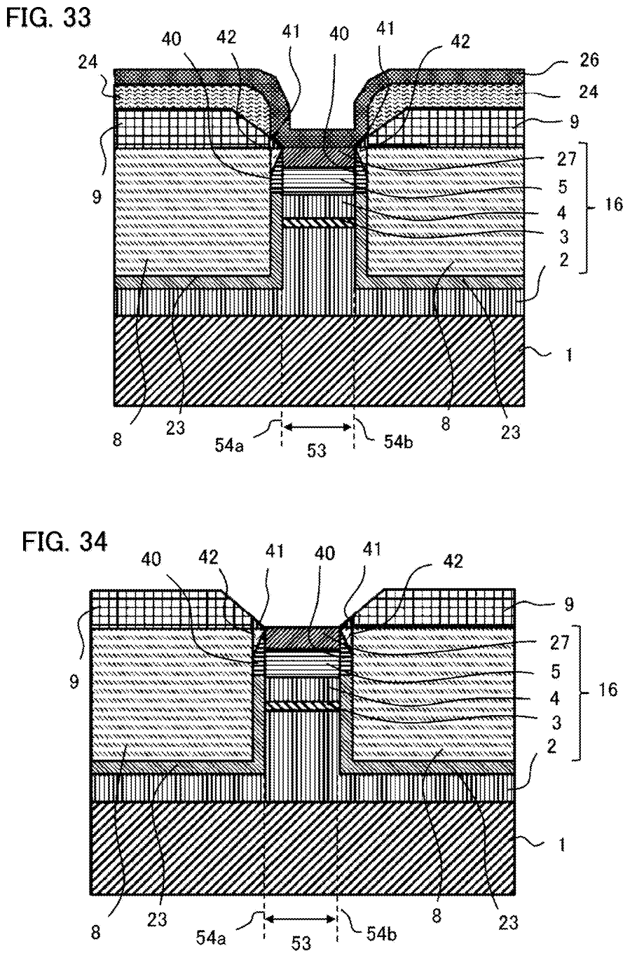

FIG. 27 is a diagram showing a cross-sectional structure of a semiconductor laser according to Embodiment 7, and FIG. 28 is an enlarged view of an area around an active layer of FIG. 27. FIG. 29 to FIG. 34 are diagrams showing a method for manufacturing the semiconductor laser of FIG. 27. The semiconductor laser 100 of Embodiment 7 is an example of a semiconductor laser in which a p-type semiconductor layer 40 is in contact with a first p-type cladding layer 27 and the active layer 5 on both the side surfaces of the ridge structure 16, and an undoped semiconductor layer 23 is in contact with both side surfaces of each layer on the side of the n-type semiconductor substrate 1 from the active layer 5 of the ridge structure 16. The semiconductor laser 100 of Embodiment 7 differs from the semiconductor laser 100 of Embodiment 2 in that the undoped semiconductor layer 23 is in contact with both the side surfaces of each layer on the side of the n-type semiconductor substrate 1 from the active layer 5 of the ridge structure 16, the first p-type cladding layer 27 is provided on the positive side of the active layer 5 in the z-direction in the ridge structure 16, and a semi-insulating layer 42 and a block layer 41 that are diffused with zinc are provided on both the side surface sides of the ridge structure 16. FIG. 27 and FIG. 28 show an example in which the p-type semiconductor layer 40 covers both the side surfaces of the ridge structure 16 from the first p-type cladding layer 27 down to the specific position of the active layer 5. The specific position is as described in Embodiment 2. The following description will focus on the differences from the semiconductor laser 100 of Embodiment 2.

The p-type semiconductor layer 40 is a semiconductor layer that is formed by diffusing zinc atoms into the undoped semiconductor layer 23 of InP to be p-type. The first p-type cladding layer 27 is a p-type cladding layer formed by diffusing zinc into the first p-type cladding layer 6 of p-type InP. The buried layer 13 covering both sides of the ridge structure 16 includes the undoped semiconductor layer 23, the p-type semiconductor layer 40, the semi-insulating layers 8 and 42, and the block layer 9.

In the semiconductor laser 100 of Embodiment 7, as in the semiconductor laser 100 of Embodiment 2, when the semiconductor laser is driven, the holes 14 as the majority carriers in the contact layer 11 and the second p-type cladding layer 10 move to the side of the active layer 5, and the hole current Ih flows. The hole current Ih is composed of the main current I1 flowing from the first p-type cladding layer 27 to the active layer 5 and the bypass current I2 flowing from the first p-type cladding layer 27 to the active layer 5 via the p-type semiconductor layer 40. The bypass current I2 is a hole current component leaking from the first p-type cladding layer 27 to the p-type semiconductor layer 40. Since the undoped semiconductor layer 23 in contact with the first n-type cladding layer 2, the diffraction grating layer 3, and the second n-type cladding layer 4 has a high resistance, the bypass current I2 cannot flow to the first n-type cladding layer 2 and the second n-type cladding layer 4 through the undoped semiconductor layer 23. Therefore, in the semiconductor laser 100 of Embodiment 7, the hole current leaking to the p-type semiconductor layer 40 is injected into the active layer 5, and is not to be the reactive current, as in the semiconductor laser 100 of Embodiment 2. Further, by bringing the p-type semiconductor layer 40, which is made p-type by the diffusion of zinc, into contact with the side surfaces of the active layer 5, it is possible to suppress overflow of an electron current from the active layer 5 to the buried layer 13.

A semiconductor laser manufacturing method for manufacturing the semiconductor laser 100 of Embodiment 7 will be described. The steps up to the ridge structure forming step of forming the ridge structure 16 are the same as the steps up to the ridge structure forming step described in Embodiment 3. After the ridge structure forming step, the undoped semiconductor layer 23 is formed by the epitaxial growth so as to cover both the side surfaces of the ridge structure 16 (undoped semiconductor layer forming step). After the undoped semiconductor layer forming step, the semi-insulating layer 8 is formed by the epitaxial growth so as to cover the surface of the undoped semiconductor layer 23 (semi-insulating layer forming step). After the semi-insulating layer forming step, the block layer 9 is formed by the epitaxial growth. FIG. 29 shows an intermediate of the semiconductor laser 100 of Embodiment 7 that has been subjected to the semi-insulating layer forming step and the step of forming the block layer 9. Thereafter, as shown in FIG. 30, the insulating film 18 is removed.

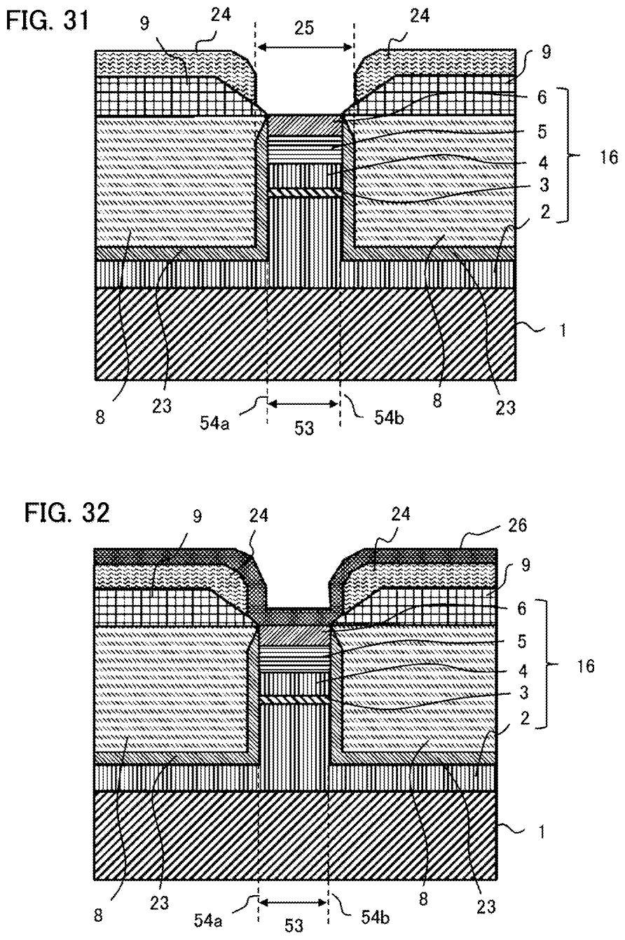

Next, a zinc diffusion step for diffusing zinc into a region from a far end of the undoped semiconductor layer 23 opposite to the n-type semiconductor substrate 1 down to the specific position of the active layer 5 will be described. First, a diffusion barrier film 24 such as SiO₂ is formed on the surface of the block layer 9 and the surface of the ridge structure 16 in the z-direction, and an opening 25 with a width in the x-direction that involves the active layer 5 and the undoped semiconductor layer 23 in contact with the active layer 5 is formed in the diffusion barrier film 24. The opening 25 is processed by using a semiconductor photolithography process. FIG. 31 shows an intermediate of the semiconductor laser 100 of Embodiment 7 in which the diffusion barrier film 24 having the opening 25 for exposing the region involving the surface of the ridge structure 16 opposite to the n-type semiconductor substrate 1 and the undoped semiconductor layer 23 in the surface of the buried layer 13 opposite to the n-type semiconductor substrate 1 is arranged on the buried layer 13.

Next, as shown in FIG. 32, a zinc oxide film (ZnO film) 26 is formed on the diffusion barrier film 24, and the surface of the ridge structure 16 on the positive side in the z-direction and the surface of the buried layer 13 that are exposed by the opening 25.

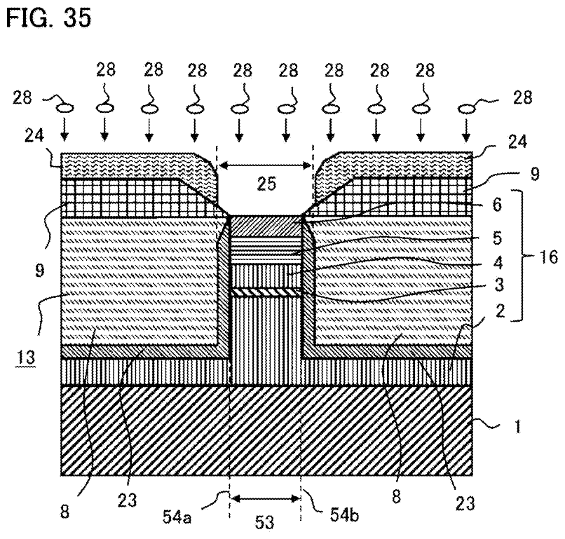

Next, the intermediate of the semiconductor laser 100 of Embodiment 7 shown in FIG. 32 is subjected to a heat treatment. In the semiconductor layers in contact with the zinc oxide film 26 in the region of the opening 25, zinc (Zn) atoms in the zinc oxide film 26 are diffused into the semiconductor layers. The zinc atoms are diffused into the first p-type cladding layer 6 and the undoped semiconductor layer 23 that are in contact with both the side surfaces from the far end of the ridge structure 16 farthest from the n-type semiconductor substrate 1 on the positive side in the z-direction down to the specific position of the active layer 5, to make the undoped semiconductor layer 23 to be a p-type layer. That is, the zinc atoms are diffused into the undoped semiconductor layer 23 that is in contact with both the side surfaces of the ridge structure 16 from the positive side end of the first p-type cladding layer 6 and the active layer 5 in the z-direction down to the specific position, and thus the undoped semiconductor layer 23 is made p-type. The heat treatment conditions to be set are heat treatment conditions under which the zinc atoms diffuse toward the negative side in the z-direction to the specific position of the active layer 5 in the semiconductor layers in contact with the ridge structure 16 in the region of the opening 25, and the zinc atoms do not diffuse to the undoped semiconductor layer 23 in contact with the first n-type cladding layer 2, the diffraction grating layer 3, and the second n-type cladding layer 4. The heat treatment conditions to be set further are heat treatment conditions under which the zinc atoms diffuse into the first p-type cladding layer 6 and the zinc atoms do not diffuse into the active layer 5 in the ridge structure 16 in the region of the opening 25. The first p-type cladding layer 6 becomes the first p-type cladding layer 27 by the diffusion of the zinc atoms. In addition, the zinc atoms also diffuse into the semiconductor layers in the region of the opening 25, that is, into the block layer 9 and the semi-insulating layer 8 on the side of the ridge structure 16, and the semiconductor layers are made to be p-type semiconductor layers. The block layer 9 and the semi-insulating layer 8 in which zinc is diffused are the semi-insulating layer 42 and the block layer 41. In the heat treatment process of the zinc diffusion step, the zinc atoms from the zinc oxide film 26 cannot diffuse through the diffusion barrier film 24 in the portion covered with the diffusion barrier film 24, and therefore, the zinc atoms do not diffuse into the semiconductor layer directly under the diffusion barrier film 24. FIG. 34 shows an intermediate of the semiconductor laser 100 of Embodiment 7 after the heat treatment in the zinc diffusion step is completed.

After the zinc diffusion step, the zinc oxide film 26 and the diffusion barrier film 24 are removed, and the second p-type cladding layer 10 and the contact layer 11 are formed on the surface of the block layer 9 and the surface of the ridge structure 16 in the z-direction. Specifically, the second p-type cladding layer 10 is formed on the surface of the block layer 9 and the surface of the ridge structure 16, and the contact layer 11 is formed on the surface of the second p-type cladding layer 10. Thereafter, the anode electrode 51 is formed to be in contact with the contact layer 11, and the cathode electrode 52 is formed to be in contact with the rear surface of the n-type semiconductor substrate 1, that is, the surface on the negative side in the z-direction.

Note that the width of the opening 25 of the diffusion barrier film 24 in FIG. 31 is appropriately adjusted so that the undoped semiconductor layer 23 in contact with the active layer 5 is made p-type by the zinc diffusion and the semi-insulating layer 8 in the x-direction relative to the p-type semiconductor layer 40 made p-type is not made to be p-type.

The semiconductor laser 100 of Embodiment 7 is the same as the semiconductor laser 100 of Embodiment 2 except for the above-described difference, and therefore, the semiconductor laser 100 of Embodiment 7 has the same effect as the semiconductor laser 100 of Embodiment 2.

As described above, the semiconductor laser 100 of Embodiment 7 is a semiconductor laser including the ridge structure 16 formed on the n-type semiconductor substrate 1 and the buried layer 13 buried so as to cover both the sides of the ridge structure opposed to each other in the direction perpendicular to the extending direction of the ridge structure 16. The ridge structure 16 includes the n-type cladding layer (second n-type cladding layer 4), the active layer 5, and the p-type cladding layer (first p-type cladding layer 27), which are sequentially formed from the side of the n-type semiconductor substrate 1. The buried layer 13 includes the p-type semiconductor layer 40 in contact with both the side surfaces of the p-type cladding layer (first p-type cladding layer 27) and the active layer 5 in the ridge structure 16, the undoped semiconductor layer 23, and the semi-insulating layer 8, and the p-type semiconductor layer 40 is not in contact with the n-type cladding layer (second n-type cladding layer 4) of the ridge structure 16. The undoped semiconductor layer 23 is in contact with both the side surfaces of the n-type cladding layer (second n-type cladding layer 4) of the ridge structure 16, and the p-type semiconductor layer 40 and the p-type cladding layer (first p-type cladding layer 27) contain zinc. In the semiconductor laser 100 of Embodiment 7, with the structure described above, the p-type semiconductor layer 40 in contact with both the side surfaces of the p-type cladding layer (first p-type cladding layer 27) and the active layer 5 in the ridge structure 16 is not in contact with the n-type cladding layer (second n-type cladding layer 4) of the ridge structure 16, and thus the reactive current that does not pass through the active layer 5 can be prevented, so that the optical output characteristics and the high-speed operation performance can be improved.

The semiconductor laser manufacturing method for manufacturing the semiconductor laser 100 of Embodiment 7 is a semiconductor laser manufacturing method for manufacturing the semiconductor laser 100 provided with the ridge structure 16 including the active layer 5 formed on the n-type semiconductor substrate 1 and the buried layer 13 buried to cover both the sides of the ridge structure opposed to each other in the direction perpendicular to the extending direction of the ridge structure 16. The buried layer 13 includes the undoped semiconductor layer 23, the p-type semiconductor layer 40, and the semi-insulating layer 8. The specific position of the active layer is set to a position of the near end of the active layer 5 on the side of the n-type semiconductor substrate 1 or a position farther from the side of the n-type semiconductor substrate 1 than the near end of the active layer 5 and not reaching the near end of the quantum well structure 35 of the active layer 5 on the side of the n-type semiconductor substrate 1. The semiconductor laser manufacturing method of Embodiment 7 includes the ridge structure forming step of sequentially forming the n-type cladding layer (second n-type cladding layer 4), the active layer 5, and the p-type cladding layer (first p-type cladding layer 6) on the n-type semiconductor substrate 1, and of forming the ridge structure 16 including the n-type cladding layer (second n-type cladding layer 4), the active layer 5, and the p-type cladding layer (first p-type cladding layer 6), with both the side surfaces exposed by etching. The semiconductor laser manufacturing method of Embodiment 7 further includes the undoped semiconductor layer forming step of forming the undoped semiconductor layer 23 so as to cover both the side surfaces of the ridge structure 16 after the ridge structure forming step, the semi-insulating layer forming step of forming the semi-insulating layer 8 so as to cover the surface of the undoped semiconductor layer 23, and the zinc diffusion step of diffusing zinc into the region from the far end of the undoped semiconductor layer 23 opposite to the n-type semiconductor substrate 1 down to the specific position of the active layer 5, and of diffusing zinc into the p-type cladding layer (first p-type cladding layer 6). The semiconductor laser manufacturing method for manufacturing the semiconductor laser 100 of Embodiment 7 can manufacture the semiconductor laser 100 in which the p-type semiconductor layer 40 in contact with both the side surfaces of the p-type cladding layer (first p-type cladding layer 27) and the active layer 5 in the ridge structure 16 is not in contact with the n-type cladding layer (second n-type cladding layer 4) of the ridge structure 16, the p-type semiconductor layer 40 and the p-type cladding layer being diffused with zinc. Therefore, the semiconductor laser 100 manufactured by the semiconductor laser manufacturing method of Embodiment 7 can prevent the reactive current that does not pass through the active layer 5, and can improve the optical output characteristics and the high-speed operation performance.

### Embodiment 8

FIG. 35 is a diagram showing a method for manufacturing a semiconductor laser according to Embodiment 8. The semiconductor laser 100 of Embodiment 8 is the same as the semiconductor laser 100 of Embodiment 7. The semiconductor laser manufacturing method for manufacturing the semiconductor laser 100 of Embodiment 8 is different from the semiconductor laser manufacturing method of Embodiment 7 in that zinc is diffused into the semiconductor layer by vapor phase diffusion using the MOCVD method in the zinc diffusion step. The following description will focus on the differences from the semiconductor laser manufacturing method of Embodiment 7.

An intermediate of the semiconductor laser 100 of Embodiment 8 at the time when zinc is diffused is the same as the intermediate of the semiconductor laser 100 of Embodiment 7 shown in FIG. 31. The diffusion barrier film 24 having the opening 25 for exposing the region involving the surface of the ridge structure 16 opposite to the n-type semiconductor substrate 1 and the undoped semiconductor layer 23 in the surface of the buried layer 13 opposite to the n-type semiconductor substrate 1 is arranged on the buried layer 13. This intermediate is placed in an apparatus for forming a film by the MOCVD method, and dimethylzinc 28 is introduced into the apparatus. By setting the pressure and temperature in the apparatus to predetermined conditions, the dimethylzinc 28 is decomposed, and zinc is diffused in the vapor phase into the semiconductor layers from the opening 25; that is, zinc is diffused into the semiconductor layers in the region of the opening 25. The predetermined pressure and temperature conditions, i.e., zinc diffusion conditions, are conditions under which zinc diffuses toward the negative side in the z-direction to the specific position of the active layer 5 in the semiconductor layer in contact with the ridge structure 16 in the region of the opening 25, and zinc do not diffuse to the undoped semiconductor layer 23 in contact with the first n-type cladding layer 2, the diffraction grating layer 3, and the second n-type cladding layer 4. Further, the zinc diffusion conditions are conditions under which zinc atoms diffuse into the first p-type cladding layer 6 and zinc atoms do not diffuse into the active layer 5, in the ridge structure 16 in the region of the opening 25.

The steps after the zinc diffusion step are the same as those in the semiconductor laser manufacturing method of Embodiment 7. The semiconductor laser 100 of Embodiment 8 is the same as the semiconductor laser 100 of Embodiment 7, and therefore, the semiconductor laser 100 of Embodiment 8 has the same effect as the semiconductor laser 100 of Embodiment 7.

### Embodiment 9

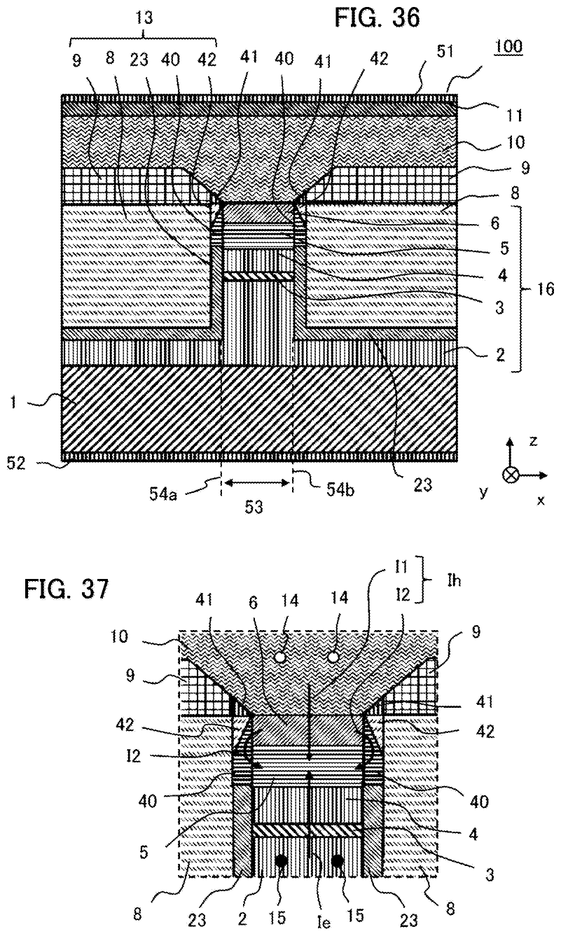

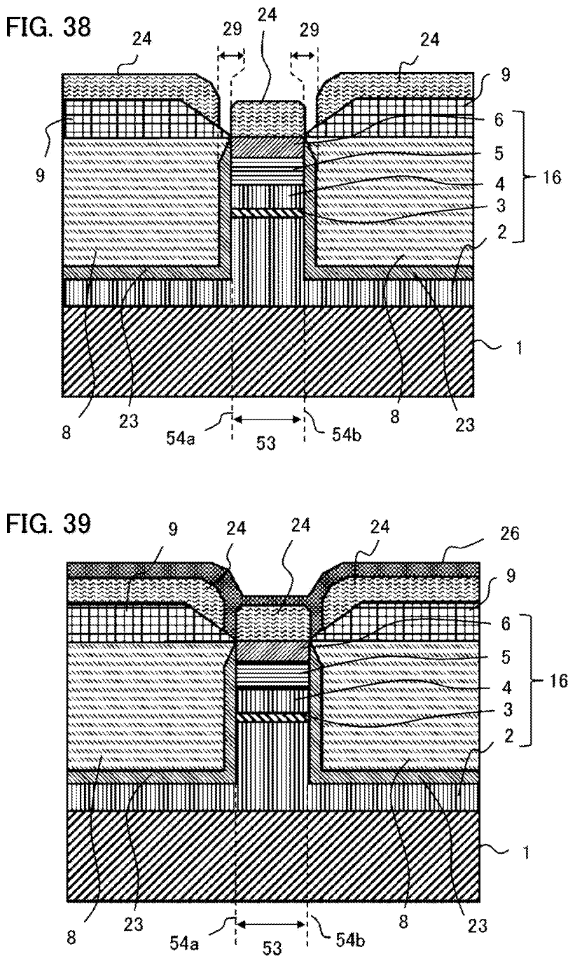

FIG. 36 is a diagram showing a cross-sectional structure of a semiconductor laser according to Embodiment 9, and FIG. 37 is an enlarged view of an area around an active layer of FIG. 36. FIG. 38 to FIG. 41 are diagrams showing a method for manufacturing the semiconductor laser of FIG. 36. The semiconductor laser 100 of Embodiment 9 is different from the semiconductor laser 100 of Embodiment 7 in that the first p-type cladding layer 6 is formed on the positive side of the active layer 5 in the z-direction. FIG. 36 and FIG. 37 show an example in which the p-type semiconductor layer 40 covers both the side surfaces of the first p-type cladding layer 6 and the active layer 5 down to the specific position of the active layer, in both the side surfaces of the ridge structure 16. The specific position is as described in Embodiment 2. The following description will focus on the differences from the semiconductor laser 100 of Embodiment 7.

The p-type semiconductor layer 40 is a semiconductor layer that is formed by diffusing zinc atoms into the undoped semiconductor layer 23 of InP to be p-type. The buried layer 13 covering both sides of the ridge structure 16 includes the undoped semiconductor layer 23, the p-type semiconductor layer 40, the semi-insulating layers 8 and 42, and the block layer 9.

In the semiconductor laser 100 of Embodiment 9, as in the semiconductor lasers 100 of Embodiment 2 and Embodiment 7, when the semiconductor laser is driven, the holes 14 as the majority carriers in the contact layer 11 and the second p-type cladding layer 10 move to the side of the active layer 5, and the hole current Ih flows. The hole current Ih is composed of the main current I1 flowing from the first p-type cladding layer 6 to the active layer 5 and the bypass current I2 flowing from the first p-type cladding layer 6 to the active layer 5 via the p-type semiconductor layer 40. The bypass current I2 is a hole current component leaking from the first p-type cladding layer 6 to the p-type semiconductor layer 40. Since the undoped semiconductor layer 23 in contact with the first n-type cladding layer 2, the diffraction grating layer 3, and the second n-type cladding layer 4 has a high resistance, the bypass current I2 cannot flow up to the first n-type cladding layer 2 and the second n-type cladding layer 4 through the undoped semiconductor layer 23. Therefore, in the semiconductor laser 100 of Embodiment 9, the hole current leaking to the p-type semiconductor layer 40 is injected into the active layer 5, and is not to be the reactive current, as in the semiconductor lasers 100 of Embodiment 2 and Embodiment 7. Further, by bringing the p-type semiconductor layer 40, which is made p-type by diffusion of zinc, into contact with the side surfaces of the active layer 5, it is possible to suppress overflow of the electron current from the active layer 5 to the buried layer 13.

In the semiconductor laser 100 of Embodiment 9, as compared with the semiconductor laser 100 of Embodiment 7, the region where zinc diffuses is limited to the portion where the undoped semiconductor layer 23 is included, and therefore, zinc does not diffuse into the first p-type cladding layer 6, and the light absorption loss of laser light caused by zinc is suppressed. Therefore, the semiconductor laser 100 of Embodiment 9 can output laser light with a higher optical output than the semiconductor laser 100 of Embodiment 7.

A semiconductor laser manufacturing method for manufacturing the semiconductor laser 100 of Embodiment 9 will be described. The ridge structure forming step of forming the ridge structure 16, the subsequent undoped semiconductor layer forming step of forming the undoped semiconductor layer 23, the semi-insulating layer forming step of forming the semi-insulating layer 8, and the step of forming the block layer 9 are the same as those in the semiconductor laser manufacturing method of Embodiment 7. Thereafter, as shown in FIG. 30, the insulating film 18 is removed, and then the zinc diffusion step of diffusing zinc into the semiconductor layers is performed.

As shown in FIG. 38, the diffusion barrier film 24 such as SiO₂ is formed on the surface of the block layers 9 and the surface of the ridge structures 16 in the z-direction, and two openings 29 having a width in the x-direction so as to involve the undoped semiconductor layer 23 in contact with the active layer 5 are formed in the diffusion barrier film 24. The openings 29 are processed by a semiconductor photolithography process. FIG. 38 shows an intermediate of the semiconductor laser 100 of Embodiment 9 in which the diffusion barrier film 24 having the openings 29 for exposing the region involving the undoped semiconductor layer 23 in the surface of the buried layer 13 opposite to the n-type semiconductor substrate 1 is arranged on the buried layer 13.

Next, as shown in FIG. 39, the zinc oxide film 26 is formed on the diffusion barrier film 24 and the surface of the buried layer 13 exposed by the openings 29.

Next, the intermediate of the semiconductor laser 100 of Embodiment 9 shown in FIG. 39 is subjected to a heat treatment. In the semiconductor layers in contact with the zinc oxide film 26 in the region of the openings 29, zinc atoms in the zinc oxide film 26 are diffused into the semiconductor layers. The zinc atoms are diffused into the undoped semiconductor layer 23 in contact with both the side surfaces in the ridge structure 16 from the far end farthest from the n-type semiconductor substrate 1 on the positive side in the z-direction down to the specific position of the active layer 5, and the undoped semiconductor layer 23 is made p-type. That is, zinc atoms are diffused into the undoped semiconductor layer 23 in contact with both the side surfaces of the ridge structure 16 from the z-direction positive side end of the active layer 5 down to the specific position, and the undoped semiconductor layer 23 is made p-type. The heat treatment conditions to be set are heat treatment conditions under which the zinc atoms diffuse toward the negative side in the z-direction to the specific position of the active layer 5 in the semiconductor layers in the region of the openings 29, and the zinc atoms do not diffuse to the undoped semiconductor layer 23 in contact with the first n-type cladding layer 2, the diffraction grating layer 3, and the second n-type cladding layer 4. In addition, the zinc atoms also diffuse into the semiconductor layers in the region of the openings 29, that is, in the block layer 9 and the semi-insulating layer 8 on the side of the ridge structure 16 to be made p-type. The block layer 9 and the semi-insulating layer 8 in which zinc is diffused are the block layer 41 and the semi-insulating layer 42.

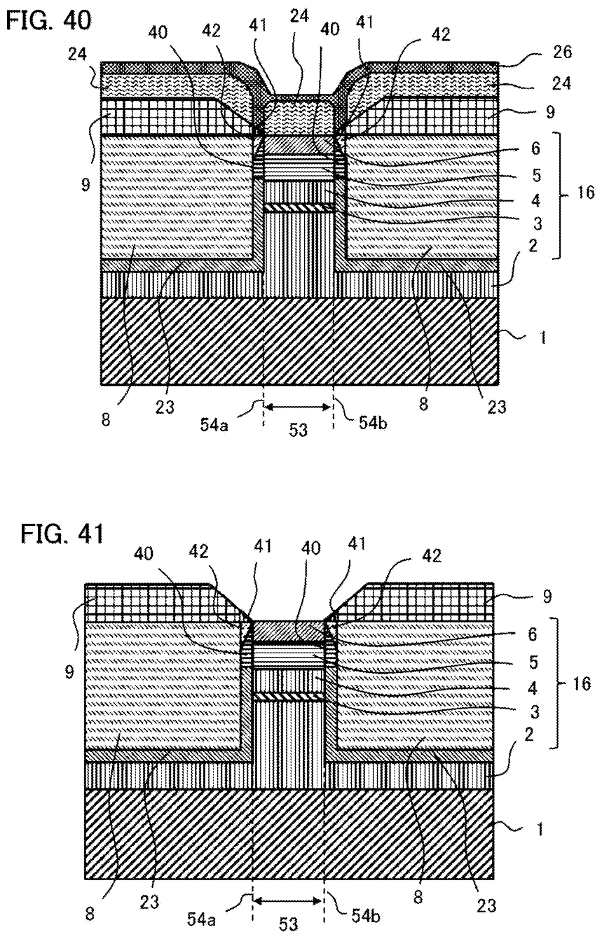

In the heat treatment of the zinc diffusion step, the zinc atoms from the zinc oxide film 26 cannot diffuse through the diffusion barrier film 24 in the portion covered with the diffusion barrier film 24, and therefore, the zinc atoms do not diffuse into the semiconductor layer directly under the diffusion barrier film 24. FIG. 40 shows an intermediate of the semiconductor laser 100 of Embodiment 9 after the heat treatment in the zinc diffusion step is completed.

After the zinc diffusion step, the zinc oxide film 26 and the diffusion barrier film 24 are removed, and the second p-type cladding layer 10 and the contact layer 11 are formed on the surface of the block layer 9 and the surface of the ridge structure 16 in the z-direction. Specifically, the second p-type cladding layer 10 is formed on the surface of the block layer 9 and the surface of the ridge structure 16, and the contact layer 11 is formed on the surface of the second p-type cladding layer 10. Thereafter, the anode electrode 51 is formed to be in contact with the contact layer 11, and the cathode electrode 52 is formed to be in contact with the rear surface of the n-type semiconductor substrate 1, that is, the surface on the negative side in the z-direction.

Note that the width of the openings 29 of the diffusion barrier film 24 in FIG. 38 is appropriately adjusted so that the undoped semiconductor layer 23 in contact with the active layer 5 is made to be p-type by the zinc diffusion and the semi-insulating layer 8 in the x-direction relative to the p-type semiconductor layer 40 made p-type is not made to be p-type.

The semiconductor laser 100 of Embodiment 9 is the same as the semiconductor laser 100 of Embodiment 7 except for the above-described difference, and therefore, the semiconductor laser 100 of Embodiment 9 has the same effect as the semiconductor laser 100 of Embodiment 7. Furthermore, as described above, in the semiconductor laser 100 of Embodiment 9, zinc is not diffused into the first p-type cladding layer 6, and the light absorption loss of laser light caused by zinc is suppressed, and therefore, laser light with a higher optical output can be output as compared with the semiconductor laser 100 of Embodiment 7.

As described above, the semiconductor laser 100 of Embodiment 9 is a semiconductor laser including the ridge structure 16 formed on the n-type semiconductor substrate 1 and the buried layer 13 buried so as to cover both the sides of the ridge structure opposed to each other in the direction perpendicular to the extending direction of the ridge structure 16. The ridge structure 16 includes the n-type cladding layer (second n-type cladding layer 4), the active layer 5, and the p-type cladding layer (first p-type cladding layer 6), which are formed sequentially from the side of the n-type semiconductor substrate 1. The buried layer 13 includes the p-type semiconductor layer 40 in contact with both the side surfaces of the p-type cladding layer (first p-type cladding layer 6) and the active layer 5 in the ridge structure 16, the undoped semiconductor layer 23, and the semi-insulating layer 8, and the p-type semiconductor layer 40 is not in contact with the n-type cladding layer (second n-type cladding layer 4) of the ridge structure 16. The undoped semiconductor layer 23 is in contact with both the side surfaces of the n-type cladding layer (second n-type cladding layer 4) of the ridge structure 16, and the p-type semiconductor layer 40 contains zinc. In the semiconductor laser 100 of Embodiment 9, with the structure described above, the p-type semiconductor layer 40 in contact with both the side surfaces of the p-type cladding layer (first p-type cladding layer 6) and the active layer 5 in the ridge structure 16 is not in contact with the n-type cladding layer (second n-type cladding layer 4) of the ridge structure 16, and thus the reactive current that does not pass through the active layer 5 can be prevented, so that the optical output characteristics and the high-speed operation performance can be improved.

The semiconductor laser manufacturing method for manufacturing the semiconductor laser 100 of Embodiment 9 is a semiconductor laser manufacturing method for manufacturing the semiconductor laser 100 provided with the ridge structure 16 including the active layer 5 formed on the n-type semiconductor substrate 1 and the buried layer 13 buried to cover both the sides of the ridge structure opposed to each other in the direction perpendicular to the extending direction of the ridge structure 16. The buried layer 13 includes the undoped semiconductor layer 23, the p-type semiconductor layer 40, and the semi-insulating layer 8. The specific position of the active layer is set to a position of the near end of the active layer 5 on the side of the n-type semiconductor substrate 1 or a position farther from the side of the n-type semiconductor substrate 1 than the near end of the active layer 5 and not reaching the near end of the quantum well structure 35 of the active layer 5 on the side of the n-type semiconductor substrate 1. The semiconductor laser manufacturing method of Embodiment 9 includes the ridge structure forming step of sequentially forming the n-type cladding layer (second n-type cladding layer 4), the active layer 5, and the p-type cladding layer (first p-type cladding layer 6) on the n-type semiconductor substrate 1, and of forming the ridge structure 16 including the n-type cladding layer (second n-type cladding layer 4), the active layer 5, and the p-type cladding layer (first p-type cladding layer 6), with both the side surfaces exposed by etching. The method for manufacturing the semiconductor laser of Embodiment 9 further includes, after the ridge structure forming step, the undoped semiconductor layer forming step of forming the undoped semiconductor layer 23 so as to cover both the side surfaces of the ridge structure 16, the semi-insulating layer forming step of forming the semi-insulating layer 8 so as to cover the surface of the undoped semiconductor layer 23, and the zinc diffusion step of diffusing zinc into the region from the far end of the undoped semiconductor layer 23 opposite to the n-type semiconductor substrate 1 down to the specific position of the active layer 5. The semiconductor laser manufacturing method for manufacturing the semiconductor laser 100 of Embodiment 9 can manufacture the semiconductor laser 100 in which the p-type semiconductor layer 40 in contact with both the side surfaces of the p-type cladding layer (the first p-type cladding layer 27) and the active layer 5 in the ridge structure 16 is not in contact with the n-type cladding layer (the second n-type cladding layer 4) of the ridge structure 16. Therefore, the semiconductor laser 100 manufactured by the semiconductor laser manufacturing method of Embodiment 9 can prevent the reactive current that does not pass through the active layer 5, and can improve the optical output characteristics and the high-speed operation performance.

### Embodiment 10

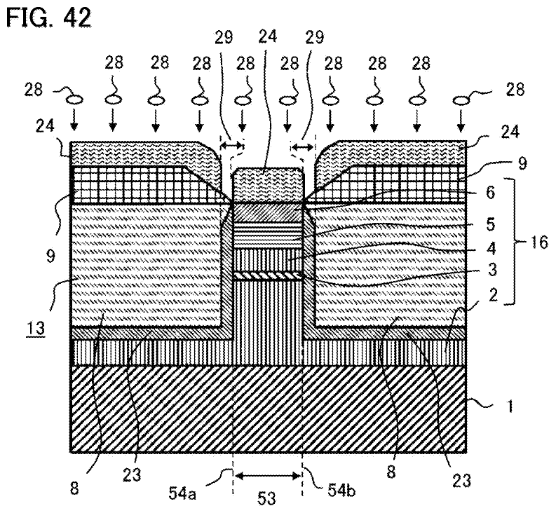

FIG. 42 is a diagram showing a method for manufacturing a semiconductor laser according to Embodiment 10. The semiconductor laser 100 of Embodiment 10 is the same as the semiconductor laser 100 of Embodiment 9. The semiconductor laser manufacturing method for manufacturing the semiconductor laser 100 of Embodiment 10 is different from the semiconductor laser manufacturing method of Embodiment 9 in that zinc is diffused into the semiconductor layers by vapor phase diffusion using the MOCVD method in the zinc diffusion step. The differences from the semiconductor laser manufacturing method of Embodiment 9 will be mainly described.

An intermediate of the semiconductor laser 100 of Embodiment 10 at the time when zinc is diffused is the same as the intermediate of the semiconductor laser 100 of Embodiment 9 shown in FIG. 38. The diffusion barrier film 24 having the openings 29 for exposing the region involving the undoped semiconductor layer 23 in the surface of the buried layer 13 opposite to the n-type semiconductor substrate 1 is arranged on the buried layer 13. This intermediate is placed in an apparatus for forming a film by the MOCVD method, and dimethylzinc 28 is introduced into the apparatus. By setting the pressure and temperature in the apparatus to predetermined conditions, the dimethylzinc 28 is decomposed, and zinc is diffused in the vapor phase into the semiconductor layers from the opening 29, that is, zinc is diffused into the semiconductor layers in the region of the openings 29. The predetermined pressure and temperature conditions, i.e., zinc diffusion conditions, are conditions under which zinc diffuses toward the negative side in the z-direction down to the specific position of the active layer 5 in the semiconductor layers in contact with the ridge structure 16 in the region of the openings 29, and zinc do not diffuse to the undoped semiconductor layer 23 in contact with the first n-type cladding layer 2, the diffraction grating layer 3, and the second n-type cladding layer 4.

The steps after the zinc diffusion step are the same as those in the semiconductor laser manufacturing method of Embodiment 9. The semiconductor laser 100 of Embodiment 10 is the same as the semiconductor laser 100 of Embodiment 9, and therefore, the same effect as the semiconductor laser 100 of Embodiment 9 is achieved.

Note that, although the example of the DFB-LD has been described as the semiconductor laser 100 in Embodiment 1 to Embodiment 10, the diffraction grating layer 3 is not formed in a case where the semiconductor laser 100 is not the DFB-LD as described in Embodiment 1 and Embodiment 3.

Note that, although various exemplary embodiments and examples are described in the present application, various features, aspects, and functions described in one or more embodiments are not inherent in a particular embodiment and can be applicable alone or in their various combinations to each embodiment. Accordingly, countless variations that are not illustrated are envisaged within the scope of the art disclosed herein. For example, the case where at least one component is modified, added or omitted, and the case where at least one component is extracted and combined with a component in another embodiment are included.

### DESCRIPTION OF REFERENCE NUMERALS AND SIGNS

1: n-type semiconductor substrate, 2: first n-type cladding layer, 3: diffraction grating layer, 4: second n-type cladding layer, 5: active layer, 6: first p-type cladding layer, 7, 7a, 7b: p-type semiconductor layer, 8: semi-insulating layer, 13: buried layer, 16: ridge structure, 17: separation portion, 20: third n-type cladding layer, 21, 21a: extending portion base layer, 22: semi-insulating layer, 23: undoped semiconductor layer, 24: diffusion barrier layer, 25: opening, 26: zinc oxide film, 29: opening, 35: quantum well structure, 39: ridge intermediate layer, 40: p-type semiconductor layer, 63: ridge main portion, 64: ridge extending portion, 66: active layer extending portion, 72: valence band energy, 74: valence band energy, 100: semiconductor laser

1. A semiconductor laser comprising:
a ridge structure formed on an n-type semiconductor substrate; and
a buried layer buried so as to cover both sides of the ridge structure opposed to each other in a direction perpendicular to an extending direction of the ridge structure, wherein
the ridge structure includes an n-type cladding layer, an active layer, and a p-type cladding layer formed sequentially from a side of the n-type semiconductor substrate,
the buried layer includes a p-type semiconductor layer in contact with both side surfaces of the p-type cladding layer and the active layer in the ridge structure, and a semi-insulating layer, the other p-type semiconductor layer on the side of the n-type semiconductor substrate of both side surfaces of the n-type cladding layer of the ridge structure, and
the p-type semiconductor layer is not in contact with the n-type cladding layer of the ridge structure,
a separation portion in which the p-type semiconductor layer and the other p-type semiconductor layer are separated from each other is formed on a side of the active layer of both the side surfaces of the n-type cladding layer of the ridge structure, and
the semi-insulating layer is embedded in the separation portion.

2. (canceled)

3. The semiconductor laser according to claim 1, wherein the semi-insulating layer is in contact with both side surfaces of the n-type cladding layer of the ridge structure.

4. The semiconductor laser according to claim 1, wherein
a stacking direction of each layer of the ridge structure is defined as a z-direction, an extending direction in which the ridge structure extends is defined as a y-direction, and a direction perpendicular to the z-direction and the y-direction is defined as an x-direction,
the ridge structure includes a ridge main portion and a ridge extending portion extending from both side surfaces of the ridge main portion in the x-direction,
the ridge extending portion is an active layer extending portion in which the active layer extends in the x-direction,
the p-type semiconductor layer is in contact with both side surfaces of the p-type cladding layer and the active layer in the x-direction and a surface of the active layer extending portion on a side opposite to the n-type semiconductor substrate, and
the separation portion is formed on the side of the n-type semiconductor substrate of the active layer extending portion.

5. The semiconductor laser according to claim 1, wherein
a stacking direction of each layer of the ridge structure is defined as a z-direction, an extending direction in which the ridge structure extends is defined as a y-direction, and a direction perpendicular to the z-direction and the y-direction is defined as an x-direction,
the ridge structure includes an extending portion base layer and another n-type cladding layer formed sequentially from the side of the n-type semiconductor substrate between the n-type cladding layer and the active layer, a ridge main portion, and a ridge extending portion extending from both side surfaces of the ridge main portion in the x-direction,
the ridge extending portion is such that the extending portion base layer, the another n-type cladding layer, and the active layer extend in the x-direction,
the p-type semiconductor layer is in contact with both side surfaces of the p-type cladding layer, the extending portion base layer, the another n-type cladding layer, and the active layer in the x-direction, and a surface of the ridge extending portion on a side opposite to the n-type semiconductor substrate, and
the separation portion is formed on the side of the n-type semiconductor substrate of the ridge extending portion.

6. The semiconductor laser according to claim 1, wherein
a stacking direction of each layer of the ridge structure is defined as a z-direction, an extending direction in which the ridge structure extends is defined as a y-direction, and a direction perpendicular to the z-direction and the y-direction is defined as an x-direction,
the ridge structure includes an extending portion base layer formed between the n-type cladding layer and the active layer, a ridge main portion, and a ridge extending portion extending from both side surfaces of the ridge main portion in the x-direction,
the ridge extending portion is such that the extending portion base layer and the active layer extend in the x-direction,
the p-type semiconductor layer is in contact with both side surfaces of the p-type cladding layer, the extending portion base layer, and the active layer in the x-direction, and a surface of the ridge extending portion on a side opposite to the n-type semiconductor substrate, and
the separation portion is formed on the side of the n-type semiconductor substrate of the ridge extending portion.

7. The semiconductor laser according to claim 5, wherein the extending portion base layer has a valence band energy level higher than a valence band energy level of the p-type semiconductor layer.

8. The semiconductor laser according to claim 7, wherein the extending portion base layer is an n-type semiconductor layer.

9. The semiconductor laser according to claim 8, wherein the extending portion base layer is an n-type AlGaInAs layer or an n-type AlInAs layer.

10. The semiconductor laser according to claim 3, wherein
the buried layer includes the other semi-insulating layer together with the semi-insulating layer formed on the side of the n-type semiconductor substrate,
the p-type semiconductor layer is formed on a surface of the semi-insulating layer on a side opposite to the n-type semiconductor substrate so as to spread in a direction away from the ridge structure, and
the other semi-insulating layer covers a surface of the p-type semiconductor layer on the side opposite to the n-type semiconductor substrate and a surface of the p-type semiconductor layer on a side of the ridge structure.

11. The semiconductor laser according to claim 1, wherein
the buried layer includes an undoped semiconductor layer,
the undoped semiconductor layer is in contact with both side surfaces of the n-type cladding layer of the ridge structure, and
the p-type semiconductor layer contains zinc.

12. The semiconductor laser according to claim 1, wherein the ridge structure includes another n-type cladding layer formed on the side of the n-type semiconductor substrate of the n-type cladding layer via a diffraction grating layer.

13. A method for producing a semiconductor laser including a ridge structure formed on an n-type semiconductor substrate and a buried layer buried to cover both sides of the ridge structure opposed to each other in a direction perpendicular to an extending direction of the ridge structure, the method comprising:
a ridge structure forming step of sequentially forming an n-type cladding layer, a ridge intermediate layer including an active layer, and a p-type cladding layer on the n-type semiconductor substrate, and of forming the ridge structure including the n-type cladding layer, the ridge intermediate layer, and the p-type cladding layer both side surfaces of which are exposed by etching;
an extending portion forming step of forming a ridge extending portion extending in a x-direction from both side surfaces of the ridge structure in the ridge intermediate layer by etching layers except for the ridge intermediate layer on both the side surfaces of the ridge structure;
a p-type semiconductor layer forming step of forming a p-type semiconductor layer so as to cover both the side surfaces of the ridge structure and a surface of the ridge extending portion on a side opposite to the n-type semiconductor substrate; and
a semi-insulating layer forming step of forming a semi-insulating layer so as to cover a surface of the p-type semiconductor layer and an exposed surface of the ridge extending portion on a side of the n-type semiconductor substrate, wherein
the buried layer includes the p-type semiconductor layer and the semi-insulating layer, and
a stacking direction of each layer of the ridge structure is defined as a z-direction, an extending direction in which the ridge structure extends is defined as a y-direction, and a direction perpendicular to the z-direction and the y-direction is defined as the x-direction.

14. The method for producing the semiconductor laser according to claim 13, wherein the ridge intermediate layer is formed only of the active layer.

15. The method for producing the semiconductor laser according to claim 13, wherein the ridge intermediate layer includes an extending portion base layer on a side of the n-type cladding layer of the active layer.

16. The method for producing the semiconductor laser according to claim 15, wherein an n-type cladding layer is included between the extending portion base layer and the active layer.

17. (canceled)

18. A method for producing a semiconductor laser provided with a ridge structure that includes an active layer and is formed on an n-type semiconductor substrate, and a buried layer buried to cover both sides of the ridge structure opposed to each other in a direction perpendicular to an extending direction of the ridge structure, the method comprising:
a ridge structure forming step of sequentially forming an n-type cladding layer, the active layer, and a p-type cladding layer on the n-type semiconductor substrate, and of forming the ridge structure including the n-type cladding layer, the active layer, and the p-type cladding layer both side surfaces of which are exposed by etching;
an undoped semiconductor layer forming step of forming an undoped semiconductor layer so as to cover both the side surfaces of the ridge structure;
a semi-insulating layer forming step of forming a semi-insulating layer so as to cover a surface of the undoped semiconductor layer; and
a zinc diffusion step of diffusing zinc into a region from a far end of the undoped semiconductor layer opposite to the n-type semiconductor substrate down to a specific position of the active layer, wherein
the buried layer includes the undoped semiconductor layer, a p-type semiconductor layer, and the semi-insulating layer, and
the specific position of the active layer is a position of a near end of the active layer on a side of the n-type semiconductor substrate or a position farther from the side of the n-type semiconductor substrate than the near end of the active layer and not reaching a near end of a quantum well structure of the active layer on the side of the n-type semiconductor substrate.

19. The method for producing the semiconductor laser according to claim 18, wherein, in the zinc diffusion step, a diffusion barrier film having an opening for exposing a region involving a surface of the ridge structure opposite to the n-type semiconductor substrate and the undoped semiconductor layer in a surface of the buried layer opposite to the n-type semiconductor substrate is arranged on the buried layer, and zinc is diffused into the undoped semiconductor layer and the p-type cladding layer from a zinc oxide film arranged to cover the opening.

20. The method for producing the semiconductor laser according to claim 18, wherein, in the zinc diffusion step, a diffusion barrier film having an opening for exposing a region involving a surface of the ridge structure opposite to the n-type semiconductor substrate and the undoped semiconductor layer in a surface of the buried layer opposite to the n-type semiconductor substrate is arranged on the buried layer, and zinc is diffused in vapor phase into the undoped semiconductor layer and the p-type cladding layer from the opening.

21. The method for producing of manufacturing the semiconductor laser according to claim 18, wherein, in the zinc diffusion step, a diffusion barrier film having an opening for exposing a region involving the undoped semiconductor layer in a surface of the buried layer opposite to the n-type semiconductor substrate is arranged on the buried layer and a surface of the ridge structure opposite to the n-type semiconductor substrate, and zinc is diffused into the undoped semiconductor layer from a zinc oxide film arranged to cover the opening.

22.-24. (canceled)
